(19) United States
(12) Patent Application Publication
(10) Pub. No.: US 2017/0248748 A1
(43) Pub. Date: Aug. 31, 2017

(54) WAVELENGTH CONVERSION MEMBER, BACKLIGHT UNIT INCLUDING WAVELENGTH CONVERSION MEMBER, AND LIQUID CRYSTAL DISPLAY DEVICE

(71) Applicant: FUJIFILM Corporation, Tokyo (JP)

(72) Inventors: Ryo SATAKE, Kanagawa (JP); Hideaki ITO, Kanagawa (JP); Makoto KAMO, Kanagawa (JP); Takashi YONEMOTO, Kanagawa (JP); Hirofumi TOYAMA, Kanagawa (JP)

(73) Assignee: FUJIFILM Corporation, Tokyo (JP)

(21) Appl. No.: 15/593,903

(22) Filed: May 12, 2017

Related U.S. Application Data
(63) Continuation of application No. PCT/JP2015/005685, filed on Nov. 13, 2015.

(30) Foreign Application Priority Data
Nov. 14, 2014 (JP) 2014-232120
Jun. 25, 2015 (JP) 2015-127583

(51) Int. Cl. F21V 8/00; G02F 1/1335; H01L 27/32

(52) U.S. Cl. CPC G02B 6/005; H01L 27/3232; G02B 6/0055; G02F 1/1336; G02B 6/0051; G02F 2001/133614; G02F 2202/36

(57) ABSTRACT

A wavelength conversion member includes: a wavelength conversion layer including at least one kind of quantum dots and a gettering agent, the quantum dots being excited by excitation light to emit fluorescence, and the gettering agent trapping at least one of water or oxygen; and a barrier layer having a moisture permeability of 0.1 g/(m²·day·atm) or lower that is formed on at least one surface of the wavelength conversion layer. The wavelength conversion layer is a layer obtained by curing a polymerizable composition including the quantum dots and the gettering agent.

### CROSS REFERENCE TO RELATED APPLICATIONS

The present application is a Continuation of PCT International Application No. PCT/JP2015/005685 filed on Nov. 13, 2015, which claims priority under 35 U.S.C. §119(a) to Japanese Patent Application No. 2014-232120 filed on Nov. 14, 2014 and Japanese Patent Application No. 2015-127583 filed on Jun. 25, 2015. Each of the above applications is hereby expressly incorporated by reference, in its entirety, into the present application.

### BACKGROUND OF THE INVENTION

1. Field of the Invention

The present invention relates to a wavelength conversion member, a backlight unit including the wavelength conversion member, and a liquid crystal display device, the wavelength conversion member including a wavelength conversion layer including quantum dots which emit fluorescence when irradiated with excitation light.

2. Description of the Related Art

A flat panel display such as a liquid crystal display device (LCD) has been more widely used as a space-saving image display device having low power consumption. A liquid crystal display device includes at least a backlight and a liquid crystal cell and typically further includes a member such as a backlight-side polarizing plate or a visible-side polarizing plate.

Recently, a configuration in which a wavelength conversion layer including quantum dots (QDs) as a light emitting material is provided in a wavelength conversion member of a backlight unit in order to improve color reproducibility of a LCD has attracted attention (refer to US2012/0113672A). The wavelength conversion member converts the wavelength of light incident from a surface light source so as to emit white light. In the wavelength conversion layer including the quantum dots as a light emitting material, white light can be realized using fluorescence which is emitted by excitation of two or three kinds of quantum dots having different light emitting properties caused by light incident from a surface light source.

The fluorescence emitted from the quantum dots has high brightness and a small full width at half maximum. Therefore, a LCD using quantum dots has excellent color reproducibility. Due to the progress of such a three-wavelength light source technique using quantum dots, the color reproduction range of a LCD has been widened from 72% to 100% in terms of the TV standard (National Television System Committee (NTSC)) ratio.

It is known that permeation of water and oxygen is necessarily suppressed in a layer including quantum dots (hereinafter, referred to as “QD layer”). In a case where water permeates into a QD layer, the dimension of the QD layer is likely to change over time, and the QD layer is likely to deteriorate in a heating step such as a dry durability test. As a result, there is a problem in that peeling is likely to occur at an interface of the QD layer. In addition, in a case where oxygen is likely to permeate into a QD layer, there is a problem in that the emission intensity decreases due to photooxidation caused by contact between quantum dots and oxygen.

In order to solve the problem, a configuration of a wavelength conversion member is disclosed in which a barrier film which suppresses permeation of water (water vapor) and oxygen is provided outside of a layer including quantum dots in order to protect the quantum dots from oxygen and water permeated from the outside of the wavelength conversion member (for example, US2012/0113672A).

Typically, for example, the following configurations of a barrier film are known: a configuration in which substrates having oxygen barrier properties and water vapor barrier properties are used as supports between which a layer including quantum dots is interposed such that the substrates themselves are used as barrier films; and a configuration in which an inorganic barrier layer or an organic barrier layer having oxygen barrier properties and water vapor barrier properties is provided on a surface of a support. As the inorganic barrier layer having oxygen barrier properties and water vapor barrier properties, an inorganic layer formed of an inorganic oxide, an inorganic nitride, an inorganic oxynitride, a metal, or the like is preferably used.

### SUMMARY OF THE INVENTION

However, the configuration of the wavelength conversion member in which a barrier film is provided outside of a layer including quantum dots as described in US2012/0113672A can suppress the permeation of oxygen and water into the layer including quantum dots to some extent but is not sufficient. In particular, for example, in a case where a wavelength conversion member having a long film shape is cut to manufacture a wavelength conversion member having a desired size, a layer including quantum dots is exposed to external air from a cut side surface. Therefore, a countermeasure against permeation of oxygen and water from the cut side surface is also required.

WO2011/031876A and WO2013/078252A disclose a configuration in which a film including quantum dots includes a light stabilizer. WO2011/031876A and WO2013/078252A describe that, since the light stabilizer is present in the layer including quantum dots, effects of oxygen and water permeated into a barrier film, effects of oxygen and water permeated from a side surface, and the like can be reduced.

However, it is necessary to add the light stabilizer to a polymerizable composition including quantum dots before curing the polymerizable composition to form a wavelength conversion layer, which may affect the curing reaction of the polymerizable composition including quantum dots.

The present invention has been made in consideration of the above-described circumstances, and an object thereof is to provide a wavelength conversion member including a wavelength conversion layer including quantum dots which emit fluorescence when irradiated with excitation light, in which the wavelength conversion member can be manufactured without adversely affecting a curing reaction of a polymerizable composition including quantum dots, peeling at an interface of the wavelength conversion layer including quantum dots is not likely to occur, and the emission intensity is not likely to decrease.

Another object of the present invention is to provide a backlight unit and a liquid crystal display device, in which peeling at an interface of a wavelength conversion layer including quantum dots is not likely to occur, the emission intensity is not likely to decrease, and the brightness is high.

According to the present invention, there is provided a wavelength conversion member comprising: a wavelength conversion layer including at least one kind of quantum dots and a gettering agent, the quantum dots being excited by excitation light to emit fluorescence, and the gettering agent trapping at least one of water or oxygen; and a barrier layer that is formed on at least a surface of the wavelength conversion layer, in which the wavelength conversion layer is a layer obtained by curing a polymerizable composition including the quantum dots and the gettering agent.

In this specification, the moisture permeability of the barrier layer is a value measured under conditions of measurement temperature: 40° C. and relative humidity: 90% RH using a method (calcium method) described in GNISATO, P. C. P. BOUTEN, P. J. SLIKKERVEER IDW Int. Display Workshop/Asia Display, 2001, 1435-1438. In this specification, the unit of the moisture permeability is [g/(m²·day·atm)]. A moisture permeability of 0.1 g/(m²·day·atm) represents that the moisture permeability is 1.14×10⁻¹¹ g/(m²·s·Pa) or lower in SI units.

In this specification, the barrier layer refers to a layer which suppresses permeation of oxygen and water. The oxygen transmission rate of the barrier layer is not particularly limited and is preferably 1.0 cm³/(m²·day·atm) or lower (1.14×10⁻¹ fm/(s·Pa) or lower in SI units). Here, the oxygen transmission rate refers to a value measured under conditions of measurement temperature: 23° C. and relative humidity: 90% RH.

It is preferable that the gettering agent is a compound or a composition on which water and oxygen are adsorbed.

The gettering agent may be evenly dispersed in the wavelength conversion layer, or may be unevenly dispersed in a layer boundary region of the wavelength conversion layer.

In this specification, “the gettering agent is evenly dispersed in the wavelength conversion layer” represents that, when a cross-section of the wavelength conversion layer in a thickness direction is observed and is divided into three regions (layer boundary sides B1 and B2 and a center layer C) in the thickness direction (refer to FIG. 7), a ratio between two of three occupied area ratios of the gettering agent in the three regions is 0.5 to 2. In addition, a ratio between the occupied area ratios is an average value of values measured in the three regions of the cross-section of the wavelength conversion layer in the thickness direction.

In addition, “the gettering agent is unevenly dispersed in the layer boundary region of the wavelength conversion layer” represents that, when the occupied area ratio of the layer boundary side B1 is represented by S_{B1} and the occupied area ratio of the layer boundary side B2 is represented by S_{B2}, a ratio of the occupied area ratio S_{B1} to the occupied area ratio S_{C} of the center layer C satisfies S_{B1}/S_{C}>2 or a ratio of the occupied area ratio S_{B2} to the occupied area ratio S_{C} of the center layer C satisfies SB₂/S_{C}>2. The occupied area ratio of the gettering agent is a value which is obtained by dividing the total occupied area of the gettering agent by the area of the cross-section of the wavelength conversion layer in the thickness direction.

Regarding the measurement of the occupied area ratios, a cross-section of the wavelength conversion layer in the thickness direction is observed with a transmission electron microscope (TEM) to measure occupied area ratios S_{B1}, S_{B2}, and S_{C} of the gettering agent particles in the measurement areas. In each region, the TEM spot size is 1 nm, and the measurement magnification is 30000 times. In each of the three regions of the layer, the measurement is measured in three visual fields. Depending on the thickness of the wavelength conversion layer and the particle size of the gettering agent, the spot size and the magnification can be appropriately adjusted.

It is preferable that the gettering agent includes at least one compound selected from the group consisting of a metal oxide, a metal halide, a metal sulfate, a metal perchlorate, a metal carbonate, a metal alkoxide, a metal carboxylate, a metal chelate, and a zeolite (aluminosilicate).

In the wavelength conversion member according to the present invention, at least one adhesive layer may be provided between the wavelength conversion layer and the barrier layer.

It is preferable that the barrier layer includes a silicon oxide, a silicon nitride, a silicon carbide, or an aluminum oxide.

It is preferable that a light diffusion layer is provided on a surface of the barrier layer opposite to a surface on the wavelength conversion layer side.

It is preferable that the barrier layer is provided on both surfaces of the wavelength conversion layer.

According to the present invention, there is provided a backlight unit comprising:

a light source that emits primary light;

the wavelength conversion member according to the present invention that is provided on the light source;

a retroreflecting member that is disposed to face the light source with the wavelength conversion member interposed therebetween; and

a reflection plate that is disposed to face the wavelength conversion member with the light source interposed therebetween,

in which the wavelength conversion member emits the fluorescence by using at least a portion of the primary light, which is emitted from the light source, as the excitation light and emits secondary light including the fluorescence.

According to the present invention, there is provided a liquid crystal display device comprising: a backlight unit; and a liquid crystal cell unit that is disposed to face the retroreflecting member side of the backlight unit.

In addition, in this specification, “full width at half maximum” of a peak refers to the width of the peak at ½ of the height of the peak. In addition, light having a center emission wavelength in a wavelength range of 430 to 480 nm is called blue light, light having a center emission wavelength in a wavelength range of 500 to 600 nm is called green light, and light having a center emission wavelength in a wavelength range of 600 to 680 nm is called red light.

The wavelength conversion member according to the present invention includes a wavelength conversion layer that includes quantum dots emitting fluorescence when irradiated with excitation light, in which a barrier layer having a moisture permeability of 0.1 g/(m²·day·atm) or lower that is formed on at least one surface of the wavelength conversion layer, and the wavelength conversion layer is a layer obtained by curing a polymerizable composition including the quantum dots and the gettering agent. In the wavelength conversion member having the above-described configuration, oxygen or water permeated into the wavelength conversion layer including quantum dots can be effectively trapped. Therefore, the dimension of the wavelength conversion layer is not likely to change over time, peeling at an interface of the wavelength conversion layer caused by deterioration in a heating step such as a dry durability test is not likely to occur, and a decrease in emission intensity caused by photooxidation of the quantum dots is small. In addition, the gettering agent does not have an adverse effect on the curing reaction of the polymerizable composition including the quantum dots.

Therefore, according to the present invention, the wavelength conversion member can be manufactured without adversely affecting a curing reaction of a polymerizable composition including quantum dots. In addition, in the wavelength conversion layer, peeling at an interface of the wavelength conversion layer including quantum dots is not likely to occur, and the emission intensity is not likely to decrease.

### BRIEF DESCRIPTION OF THE DRAWINGS

FIG. 1 is a cross-sectional view showing a schematic configuration of a backlight unit including a wavelength conversion member according to an embodiment of the present invention.

FIG. 2A is a cross-sectional view showing a schematic configuration of a wavelength conversion member according to a first embodiment of the present invention.

FIG. 2B is a cross-sectional view showing a schematic configuration of a wavelength conversion member according to a second embodiment of the present invention.

FIG. 3A is a cross-sectional view showing a schematic configuration of a wavelength conversion member according to a third embodiment of the present invention.

FIG. 3B is a cross-sectional view showing a schematic configuration of a wavelength conversion member according to a fourth embodiment of the present invention.

FIG. 4 is a diagram showing a schematic configuration of an example of a device of manufacturing a wavelength conversion member according to an embodiment of the present invention.

FIG. 5 is an enlarged view showing a part of the manufacturing device shown in FIG. 4.

FIG. 6 is a cross-sectional view showing a schematic configuration of a liquid crystal display device including a backlight unit according to an embodiment of the present invention including.

FIG. 7 is a schematic diagram for describing the definition of a configuration in which a gettering agent is dispersed in the present invention.

### DESCRIPTION OF THE PREFERRED EMBODIMENTS

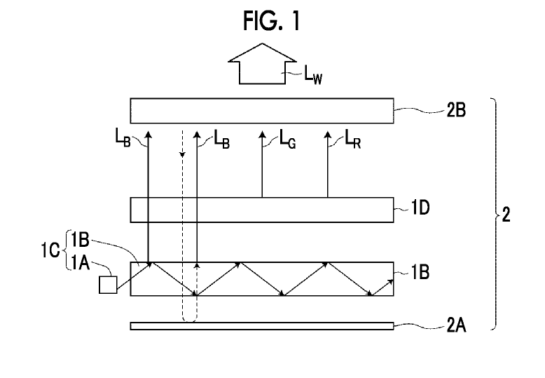

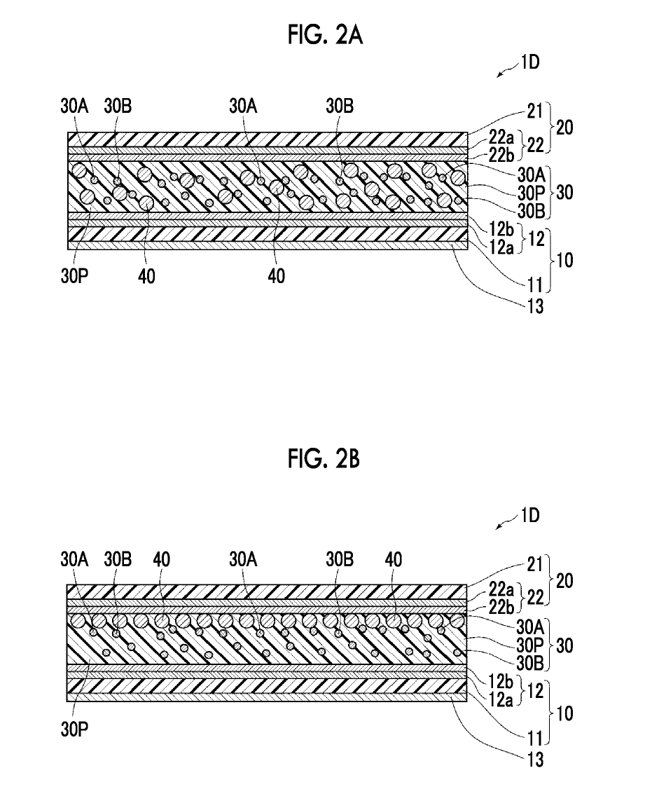

A wavelength conversion member according to an embodiment of the present invention and a backlight unit including the wavelength conversion member will be described with reference to the drawings. FIG. 1 is a cross-sectional view showing a schematic configuration of a backlight unit including a wavelength conversion member according to an embodiment of the present invention. FIGS. 2A and 2B are cross-sectional views showing schematic configurations of wavelength conversion members according to a first embodiment and a second embodiment of the present invention, respectively. In the drawings of this specification, dimensions of respective portions are appropriately changed in order to easily recognize the respective portions. In this specification, numerical ranges represented by “to” include numerical values before and after “to” as lower limit values and upper limit values.

As shown in FIG. 1, a backlight unit 2 includes: a surface light source 1C including a light source 1A, which emits primary light (blue light L_{B}), and a light guide plate 1B which guides and emits the primary light emitted from the light source 1A; a wavelength conversion member 1D that is provided on the surface light source 1C; a retroreflecting member 2B that is disposed to face the surface light source 1C with the wavelength conversion member 1D interposed therebetween; and a reflection plate 2A that is disposed to face the wavelength conversion member 1D with the surface light source 1C interposed therebetween.

The wavelength conversion member 1D are excited by excitation light, which is at least a portion of the excitation light L_{B} emitted from the surface light source 1C, to emit fluorescence and emits secondary light (L_{G}, L_{R}) which includes the fluorescence and the primary light L_{B} which has passed through the wavelength conversion member 1D.

The shape of the wavelength conversion member 1D is not particularly limited and may be an arbitrary shape such as a sheet shape or a bar shape.

In FIG. 1, L_{B}, L_{G}, and L_{R} emitted from the wavelength conversion member 1D are incident on the retroreflecting member 2B, and each incident light is repeatedly reflected between the retroreflecting member 2B and the reflection plate 2A and passes through the wavelength conversion member 1D multiple times. As a result, in the wavelength conversion member 1D, a sufficient amount of the excitation light (blue light L_{B}) is absorbed by quantum dots 30A and 30B, a sufficient amount of fluorescence (L_{G}, L_{R}) is emitted, and white light L_{W} is realized and emitted from the retroreflecting member 2B.

In a case where ultraviolet light is used as the excitation light, by causing ultraviolet light as excitation light to be incident on a wavelength conversion layer 30 including quantum dots 30A, 30B, and 30C, white light can be realized by red light emitted from the quantum dots 30A, green light emitted from the quantum dots 30B, and blue light emitted from the quantum dots 30C.

[Wavelength Conversion Member]

The wavelength conversion member 1D includes: the wavelength conversion layer 30 including the quantum dots 30A and 30B which are excited by the excitation light (L_{B}) to emit the fluorescence (L_{G}, L_{R}); and barrier layers 12 and 22 which are formed on surfaces of the wavelength conversion layer 30 (FIGS. 2A and 2B).

In FIGS. 2A and 2B, in the wavelength conversion member 1D, the upper side (the barrier film 20 side) is the retroreflecting member 2B side in the backlight unit 2, and the lower side (the barrier film 10 side) is the surface light source 1C side in the backlight unit 2. Permeation of oxygen and water, which has permeated into the wavelength conversion member 1D, into the wavelength conversion layer 30 from the retroreflecting member 2B side and the surface light source 1C side is suppressed by the barrier films 10 and 20.

As described above in “SUMMARY OF THE INVENTION”, the configuration where a barrier film is provided outside of a layer including quantum dots in a wavelength conversion member can suppress the permeation of oxygen and water into the layer including quantum dots to some extent but is not sufficient. The present inventors performed a thorough investigation on a method in which oxygen and water permeated into a wavelength conversion layer are trapped in the wavelength conversion layer to prevent deterioration of a wavelength conversion layer and a decrease in emission intensity.

The present inventors performed an investigation on a trapping agent for trapping oxygen or water which has no adverse affect on a curing reaction of a polymerizable composition including quantum dots even when added to the polymerizable composition. As a result, it was found that a gettering agent is preferable as the trapping agent and can effectively trap oxygen or water which permeates into a wavelength conversion layer including quantum dots, the gettering agent being added to a sealing portion or the like in an organic EL element or the like in order to suppress permeation of external oxygen and water into a photoelectric conversion portion.

In a case where a gettering agent is added to a light emitting layer, the light emitting performance deteriorates. Therefore, in general, a gettering agent is added to a sealing portion in an organic EL element, is provided outside of an organic EL element and sealed. The present inventors found that, in a case where a gettering agent is added to a wavelength conversion layer of a wavelength conversion member, the gettering agent functions not only as a trapping agent for trapping water and oxygen but also a scatterer. As a result, an effect of trapping water and oxygen, an effect of scattering primary light in the wavelength conversion layer with high efficiency so as to significantly improve the wavelength conversion efficiency, and an effect of significantly improving the emission brightness illuminance are exhibited.

That is, as shown in FIGS. 2A and 2B, the wavelength conversion member 1D includes: the wavelength conversion layer 30 including the quantum dot 30A and 30B and a gettering agent 40, the quantum dots 30A and 30B being excited by the excitation light (L_{B}) to emit the fluorescence (L_{G}, L_{R}), and the gettering agent 40 trapping at least one of water or oxygen; and the barrier layers 12 and 22 which are formed on surfaces of the wavelength conversion layer 30. The wavelength conversion layer 30 is a layer obtained by curing a polymerizable composition including the quantum dots 30A and 30B and the gettering agent 40.

In the first embodiment and the second embodiment, the barrier films 10 and 20 are provided on opposite main surfaces of the wavelength conversion layer 30, and the barrier films 10 and 20 include supports 11 and 21 and barrier layers 12 and 22 supported on surfaces of the supports 11 and 21, respectively.

In the two embodiments, the barrier films 10 and 20 are disposed such that the barrier layers 12 and 22 are positioned on the wavelength conversion layer 30 side, but the present invention is not limited to this configuration.

In addition, in the embodiment, the barrier layers 12 and 22 are formed on the supports 11 and 21, respectively, but the present invention is not limited to this configuration. Each of the barrier films 10 and 20 may include only a support, or may include a barrier layer that is not formed on a support.

In the wavelength conversion member 1D, the barrier film 10 includes an unevenness imparting layer (mat layer) 13 which imparts an uneven structure to a surface of the barrier film 10 opposite to the wavelength conversion layer 30 side. In the embodiment, the unevenness imparting layer 13 also functions as a light diffusion layer.

Hereinafter, each component of the wavelength conversion member 1D will be described, and then a method of manufacturing the wavelength conversion member will be described.

[Wavelength Conversion Layer]

In the wavelength conversion layer 30, the quantum dots 30A and the quantum dots 30B are dispersed in an organic matrix 30P, in which the quantum dots 30A are excited by the blue light L_{B} to emit the fluorescence (red light) L_{R}, and the quantum dots 30A are excited by the blue light L_{B} to emit the fluorescence (green light) L_{G}. In FIGS. 2A and 2B, the quantum dots 30A and 30B are enlarged and shown in order to easily recognize the quantum dots. Actually, for example, the thickness of the wavelength conversion layer 30 is 50 to 100 μm, and the diameter of the quantum dot is about 2 to 7 nm.

The thickness of the wavelength conversion layer 30 is preferably in a range of 1 to 500 μm, more preferably in a range of 10 to 250 μm, and still more preferably in a range of 30 to 150 μm. It is preferable that the thickness is 1 μm or more because a high wavelength conversion effect can be obtained. In addition, it is preferable that the thickness is 500 μm or less because, in a case where the wavelength conversion member is incorporated into a backlight unit, the thickness of the backlight unit can be reduced.

Alternatively, in the wavelength conversion layer 30, the quantum dots 30A, the quantum dots 30B, and the quantum dots 30C may be dispersed in the organic matrix 30P, in which the quantum dots 30A are excited by ultraviolet light L_{UV} to emit the fluorescence (red light) L_{R}, the quantum dots 30B are excited by the ultraviolet light L_{UV} to emit the fluorescence (green light) L_{G}, and the quantum dots 30C are excited by the ultraviolet light L_{UV} to emit the fluorescence (blue light) L_{B}. The shape of the wavelength conversion layer is not particularly limited and may be an arbitrary shape.

The first embodiment and the second embodiment are different from each other in the state where the gettering agent 40 is dispersed in the wavelength conversion layer 30. As shown in the drawings, in the first embodiment, the gettering agent 40 is evenly dispersed in the wavelength conversion layer 30. In the second embodiment, the gettering agent 40 is unevenly dispersed in a layer boundary region between the wavelength conversion layer 30 and the barrier layer 22 adjacent to the wavelength conversion layer 30.

As described above, the gettering agent 40 is a material that traps at least one of oxygen or water. Therefore, in a case where the gettering agent 40 is unevenly dispersed in the wavelength conversion layer 30, an effect of trapping water and/or oxygen permeated into the wavelength conversion layer 30 is exhibited. In addition, as described above, the gettering agent present in the wavelength conversion layer 30 functions not only as a trapping agent for trapping water and oxygen but also a scatterer. As a result, an effect of scattering primary light in the wavelength conversion layer with high efficiency so as to significantly improve the wavelength conversion efficiency is exhibited, and an effect of improving the emission brightness is also exhibited.

In the configuration where the gettering agent 40 is evenly dispersed in the wavelength conversion layer 30 as in the first embodiment shown in FIG. 2A, not only oxygen or water permeated through the barrier layer but also oxygen or water permeated from a side surface can be efficiently trapped. Further, in the first embodiment, the effect as the scatterer can be obtained over the entire region of the wavelength conversion layer 30. Therefore, the amount of returned light of the primary light emitted from the quantum dots in the wavelength conversion layer is significantly increased, and the effect of improving the conversion efficiency can be further increased.

In addition, in an embodiment, the gettering agent 40 is formed of fine particles of an inorganic material described below. Therefore, by dispersing the gettering agent 40 to be evenly present in the wavelength conversion layer, the gettering agent 40 functions as an inorganic filler (for example, an effect of improving shape stability, an effect of improving mechanical strength, or an effect of improving heat resistance). Accordingly, in the first embodiment, not only an effect of improving dimension stability obtained by trapping oxygen or water but also an effect of improving dimension stability obtained by an inorganic filler can be exhibited. As a result, a wavelength conversion member in which peeling at an interface of the wavelength conversion layer is not likely to occur can be realized.

On the other hand, in the configuration where the gettering agent 40 is unevenly dispersed in a layer boundary region between the wavelength conversion layer 30 and the barrier layer 22 adjacent to the wavelength conversion layer 30 as in the second embodiment shown in FIG. 2B, oxygen or water permeated into the barrier layer can be more efficiently trapped. Further, in the second embodiment, the effect as the scatterer can be effectively obtained on the light exit side of the wavelength conversion layer 30. Therefore, the effect of improving the emission brightness can be more significantly obtained.

In the first embodiment and the second embodiment, a coating layer with which a surface of the wavelength conversion layer 30 is coated may be provided between the wavelength conversion layer 30 and the barrier layer 22 (not shown). The coating layer has, for example, a function of smoothing the outermost surface of the QD layer to improve adhesiveness with the barrier layer, a function of protecting the QD layer, or a function of adjusting optical characteristics.

In the first and second embodiments, the organic matrix 30P includes a polymer, and the wavelength conversion layer 30 can be formed of a polymerizable composition including the quantum dots 30A and 30B, the gettering agent 40, and a polymerizable compound which forms the organic matrix 30P after polymerized (hereinafter, referred to simply as “quantum dot-containing polymerizable composition”). That is, the wavelength conversion layer 30 is a cured layer obtained by curing the quantum dot-containing polymerizable composition. In addition, the gettering agent 40 does not have an adverse effect on the curing reaction of the polymerizable composition including the quantum dots.

Therefore, in the wavelength conversion member 1D, permeation of oxygen or water into the wavelength conversion layer 30 including quantum dots can be effectively suppressed. Therefore, the dimension of the wavelength conversion layer 30 is not likely to change over time, peeling at an interface of the wavelength conversion layer caused by deterioration in a heating step such as a dry durability test is not likely to occur, a decrease in emission intensity caused by photooxidation of the quantum dots is small, and the wavelength conversion member 1D can be manufactured without adversely affecting the curing reaction of the quantum dot-containing polymerizable composition.

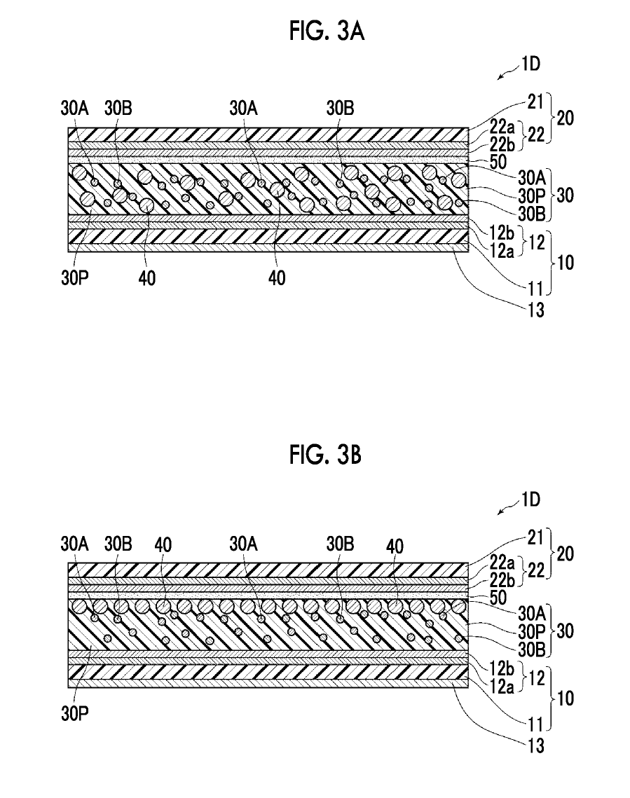

FIGS. 3A and 3B show configurations (a third embodiment and a fourth embodiment) of the wavelength conversion members shown in FIGS. 2A and 2B in which an adhesive layer 50 is provided between the wavelength conversion layer 30 and the barrier layer 22. Although the details will be described below, in the wavelength conversion member 1D according to the first and second embodiments shown in FIGS. 2A and 2B, the wavelength conversion layer 30 is formed by forming the coating film of the quantum dot-containing polymerizable composition on the barrier film 10, laminating the barrier film 20 before curing the coating film, and then curing the coating film. Therefore, the adhesive layer is not necessary between the wavelength conversion layer 30 and the barrier layer 22. On the other hand, the wavelength conversion member 1D shown in FIGS. 3A and 3B is manufactured by forming the coating film of the quantum dot-containing polymerizable composition on the barrier film 10, curing the coating film to form the wavelength conversion layer 30, and then laminating the barrier film 20. Accordingly, the wavelength conversion layer 30 and the barrier layer 22 are adhered to each other through the adhesive layer 50.

The configurations shown in FIGS. 3A and 3B are the same as those shown in FIGS. 2A and 2B, except that the adhesive layer 50 is provided. Therefore, in the embodiments shown in FIGS. 3A and 3B, the same effects as those in the first embodiment and the second embodiment are exhibited.

Next, the quantum dot-containing polymerizable composition will be described.

<Quantum Dot-Containing Polymerizable Composition>

The quantum dot-containing polymerizable composition includes the quantum dots 30A and 30B, the gettering agent 40, and the polymerizable compound which forms the organic matrix 30P after polymerized. In addition to the above-described components, the quantum dot-containing polymerizable composition may further include other components such as a polymerization initiator or a silane coupling agent.

A method of preparing the quantum dot-containing polymerizable composition is not particularly limited. The quantum dot-containing polymerizable composition may be prepared according to a preparation procedure of a general polymerizable composition. It is preferable that the gettering agent is added at a final stage of the preparation of the composition in order to reduce factors which impairs oxygen and water trapping properties of the gettering agent.

(Quantum Dots)

The quantum dots may include two or more kinds of quantum dots having different light emitting properties. In the embodiment, the quantum dots include the quantum dots 30A which are excited by the blue light L_{B} to emit the fluorescence (red light) L_{R} and the quantum dots 30B which are excited by the blue light L_{B} to emit the fluorescence (green light) L_{G}. In addition, the quantum dots may include the quantum dots 30A which are excited by the ultraviolet light L_{UV} to emit the fluorescence (red light) L_{R}, the quantum dots 30B which are excited by the ultraviolet light L_{UV} to emit the fluorescence (green light) L_{G}, and the quantum dots 30C which are excited by the ultraviolet light L_{UV} to emit the fluorescence (blue light) L_{B}.

Examples of well-known kinds of quantum dots include the quantum dots 30A (which emit red light) having a center emission wavelength in a wavelength range of 600 nm to 680 nm, the quantum dots 30B (which emit green light) having a center emission wavelength in a wavelength range of 500 nm to 600 nm, and the quantum dots 30C (which emit blue light) having a center emission wavelength in a wavelength range of 400 nm to 500 nm.

In addition to the above description, the details of the quantum dots can be found in, for example, paragraphs “0060” to “0066” of JP2012-169271A, but the present invention is not limited thereto. As the quantum dots, a commercially available product can be used without any particular limitation. The emission wavelength of the quantum dots can be typically adjusted by adjusting the composition of particles, the size of particles, or both the composition and the size of particles.

The quantum dots may be added to the polymerizable composition in the form of particles or in the form of a dispersion in which they are dispersed in a solvent. It is preferable that the quantum dots are added in the form of a dispersion from the viewpoint of suppressing aggregation of particles of the quantum dots. The solvent used herein is not particularly limited. For example, 0.01 parts by mass to 10 parts by mass of the quantum dots can be added to the quantum dot-containing polymerizable composition with respect to 100 parts by mass of the total mass of the polymerizable composition.

The content of the quantum dots in the quantum dot-containing polymerizable composition is preferably 0.01 to 10 mass % and more preferably 0.05 to 5 mass % with respect to the total mass of the polymerizable compound in the polymerizable composition.

(Gettering Agent)

In the embodiment, the gettering agent is a compound or a composition which traps at least one of water or oxygen and does not have an adverse effect on the curing of the quantum dot-containing polymerizable composition, for example, does not inhibit the polymerization of the polymerizable compound. It is preferable that the gettering agent 40 is a compound or a composition on which water and oxygen are adsorbed. In addition, it is preferable that the gettering agent 40 has an excellent function as the scatterer.

As the gettering agent 40, a well-known material which is used as a gettering agent of an organic EL element can be used. The gettering agent 40 may be an inorganic gettering agent or an organic gettering agent. It is preferable that the gettering agent 40 includes at least one compound selected from the group consisting of a metal oxide, a metal halide, a metal sulfate, a metal perchlorate, a metal carbonate, a metal alkoxide, a metal carboxylate, a metal chelate, and a zeolite (aluminosilicate).

Examples of the gettering agent include calcium oxide (CaO), barium oxide (BaO), magnesium oxide (MgO), strontium oxide (SrO), lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂), and nickel sulfate (NiSO₄).

The organic gettering agent is not particularly limited as long as it is a material which absorbs water through a chemical reaction and does not become opaque before and after the reaction. In particular, an organic metal compound such as a metal alkoxide, a metal carboxylate, or a metal chelate is preferable due to its water trapping ability. Here, the organic metal compound refers to a compound having a metal-carbon bond, a metal-oxygen bond, or a metal-nitrogen bond. In a case where water and the organic metal compound react with each other, the above-described bond is cut through a hydrolysis reaction, and a metal hydroxide is obtained. Depending on the metal, hydrolysis and polycondensation are performed on the metal hydroxide after the reaction to increase the molecular weight thereof.

As the metal of the metal alkoxide, the metal carboxylate, or the metal chelate, a metal which is highly reactive with water in the form of an organic metal compound, that is, a metal atom which is easily cut from various bonds by water is preferably used. Specific examples of the metal include aluminum, silicon, titanium, zirconium, bismuth, strontium, calcium, copper, sodium, and lithium. Other examples of the metal include cesium, magnesium, barium, vanadium, niobium, chromium, tantalum, tungsten, indium, and iron. In particular, a desiccant of an organic metal compound having aluminum as a central metal is preferable from the viewpoints of dispersibility in a resin and reactivity with water. Examples of the organic group include: an alkoxy group or a carboxyl group including an unsaturated hydrocarbon, a saturated hydrocarbon, a branched unsaturated hydrocarbon, a branched saturated hydrocarbon, or a cyclic hydrocarbon, for example, a methoxy group, an ethoxy group, a propoxy group, a butoxy group, a 2-ethylhexyl group, an octyl group, a decyl group, a hexyl group, an octadecyl group, or an stearyl group; and a β-dikenato group such as an acetylacetonato group or a dipivaloylmethanato group.

Among these, an aluminum ethylacetoacetate having 1 to 8 carbon atoms which is represented by the following formula shown in [Chem. 1] is preferably used from the viewpoint that a sealing composition having excellent transparency can be formed.

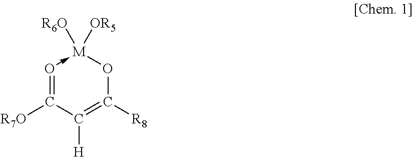

(wherein R₅ to R₈ each independently represent an organic group such as an alkyl group having 1 to 8 carbon atoms, an aryl group, an alkoxy group, a cycloalkyl group, or an acyl group; M represents a trivalent metal atom; and the organic groups represented by R₅ to R₈ may be the same as or different from each other.)

The aluminum ethylacetoacetate having 1 to 8 carbon atoms is commercially available from, for example, Kawaken Fine Chemicals Co., Ltd. or Hope Chemical Co., Ltd.

The gettering agent 40 is in the form of particles or powder. The average particle size of the gettering agent 40 is typically in a range of less than 20 μm and is preferably 10 μm or less, more preferably 2 μm or less, and still more preferably 1 μm or less. From the viewpoint of scattering properties, the average particle size of the gettering agent 40 is preferably 0.3 to 2 μm and more preferably 0.5 to 1.0 μm. The average particle size described herein refers to an average value of particle sizes calculated from a particle size distribution which is measured using a dynamic light scattering method.

From the viewpoint of the effect of trapping oxygen or water, the content of the gettering agent in the quantum dot-containing polymerizable composition is preferably 0.1 mass % or higher, more preferably 0.5 mass % or higher, and still more preferably 1 mass % or higher with respect to the total mass of the quantum dot-containing polymerizable composition. On the other hand, the gettering agent may be modified by adsorption of water or oxygen. The modified gettering agent may induce decomposition of the quantum dot-containing polymerizable composition, which may lead to deterioration in adhesiveness, brittleness, and quantum dot emission efficiency. From the viewpoint of the deterioration, the content of the gettering agent is preferably 20 mass %% or lower, more preferably 15 mass % or lower, and still more preferably 10 mass % or lower.

(Polymerizable Compound)

The polymerizable compound in the quantum dot-containing polymerizable composition is not particularly limited and is preferably a radically polymerizable compound. From the viewpoints of transparency, adhesiveness, and the like of the cured coating film, it is preferable that the radically polymerizable compound is a monofunctional or polyfunctional (meth)acrylate monomer. If polymerizable, the radically polymerizable compound may be a prepolymer or a polymer of the monofunctional or polyfunctional (meth)acrylate monomer. In this specification, “(meth)acrylate” represents “either or both of acrylate and methacrylate”. The same shall be applied to “(meth)acryloyl”.

As the monofunctional (meth)acrylate monomer, for example, acrylic acid, methacrylic acid, or a derivative thereof can be used. More specifically, a monomer having one polymerizable unsaturated bond ((meth)acryloyl group) of (meth)acrylic acid in the molecule can be used.

Specific examples include: an alkyl (meth)acrylate with an alkyl group having 1 to 30 carbon atoms such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, or stearyl (meth)acrylate; an aralkyl (meth)acrylate with an alkyl group having 7 to 20 carbon atoms such as benzyl (meth)acrylate; an alkoxyalkyl (meth)acrylate with an alkoxyalkyl group having 2 to 30 carbon atoms such as butoxyethyl (meth)acrylate; an aminoalkyl (meth)acrylate with a (monoalkyl or dialkyl)aminoalkyl group having 1 to 20 carbon atoms in total such as N,N-dimethylaminoethyl (meth)acrylate; a polyalkylene glycol alkyl ether (meth)acrylate with an alkylene chain having 1 to 10 carbon atoms and a terminal alkyl ether having 1 to 10 carbon atoms such as diethylene glycol ethyl ether (meth)acrylate, triethylene glycol butyl ether (meth)acrylate, tetraethylene glycol monomethyl ether (meth)acrylate, hexaethylene glycol monomethyl ether (meth)acrylate, octaethylene glycol monomethyl ether (meth)acrylate, nonaethylene glycol monomethyl ether (meth)acrylate, dipropylene glycol monomethyl ether (meth)acrylate, heptapropylene glycol monomethyl ether (meth)acrylate, or tetraethylene glycol monoethyl ether (meth)acrylate; a polyalkylene glycol aryl ether (meth)acrylate with an alkylene chain having 1 to 30 carbon atoms and a terminal aryl ether having 6 to 20 carbon atoms such as hexaethylene glycol phenyl ether (meth)acrylate; a (meth)acrylate having an alicyclic structure and having 4 to 30 carbon atoms in total such as cyclohexyl (meth)acrylate, dicyclopentanyl (meth)acrylate, isobornyl (meth)acrylate, or a methylene oxide adduct of cyclodecatriene (meth)acrylate; a fluorinated alkyl(meth)acrylate having 4 to 30 carbon atoms in total such as heptadecafluorodecyl (meth)acrylate; a (meth)acrylate having a hydroxyl group such as 2-hydroxyethyl (meth)acrylate, 3-hydroxypropyl (meth)acrylate, 4-hydroxybutyl (meth)acrylate, triethylene glycol mono(meth)acrylate, tetraethylene glycol mono(meth)acrylate, hexaethylene glycol mono(meth)acrylate, octapropylene glycol mono(meth)acrylate, or glycerol mono(meth)acrylate or di(meth)acrylate; a (meth)acrylate having a glycidyl group such as glycidyl (meth)acrylate; a polyethylene glycol mono(meth)acrylate with an alkylene chain having 1 to 30 carbon atoms such as tetraethylene glycol mono(meth)acrylate, hexaethylene glycol mono(meth)acrylate, or octapropylene glycol mono(meth)acrylate; and a (meth)acrylamide such as (meth)acrylamide, N,N-dimethyl (meth)acrylamide, N-isopropyl (meth)acrylamide, 2-hydroxyethyl (meth)acrylamide, or acryloylmorpholine.

The monofunctional (meth)acrylate monomer is not limited to this examples.

As the monofunctional (meth)acrylate monomer, an alkyl (meth)acrylate having 4 to 30 carbon atoms is preferable, and an alkyl (meth)acrylate having 12 to 22 carbon atoms is more preferable from the viewpoint of dispersibility of quantum dots. As the dispersibility of the quantum dots is improved, the amount of light directed from the wavelength conversion layer to an exit surface increases, which is efficient for improving front brightness and front contrast. Specifically, as the monofunctional (meth)acrylate monomer, for example, butyl (meth)acrylate, octyl (meth)acrylate, lauryl (meth)acrylate, oleyl (meth)acrylate, stearyl (meth)acrylate, behenyl (meth)acrylate, butyl (meth)acrylamide, octyl (meth)acrylamide, lauryl (meth)acrylamide, oleyl (meth)acrylamide, stearyl (meth)acrylamide, or behenyl (meth)acrylamide is preferable. Among these, lauryl (meth)acrylate, oleyl (meth)acrylate, or stearyl (meth)acrylate is more preferable.

A monomer having one polymerizable unsaturated bond ((meth)acryloyl group) of the (meth)acrylic acid in the molecule and a polyfunctional (meth)acrylate monomer having two or more (meth)acryloyl groups in the molecule can also be used in combination.

Preferable examples of a bifunctional (meth)acrylate monomer among the bifunctional or higher (meth)acrylate monomers include neopentyl glycol di(meth)acrylate, 1,9-nonanediol di(meth)acrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, dicyclopentenyl (meth)acrylate, dicyclopentenyloxyethyl (meth)acrylate, and dicyclopentanyl di(meth)acrylate.

In addition, preferable examples of a trifunctional (meth)acrylate monomer among the bifunctional or higher (meth)acrylate monomers include epichlorohydrin (ECH)-modified glycerol tri(meth)acrylate; ethylene oxide (EO)-modified glycerol tri(meth)acrylate, propylene oxide (PO)-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxy enta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxy tetra(meth)acrylate, and pentaerythritol tetra(meth)acrylate.

It is preferable that the quantum dot-containing polymerizable composition includes, as the radically polymerizable compound, a (meth)acrylate monomer in which a ratio Mw/F of the molecular weight Mw of the radically polymerizable compound to the number F of (meth)acryloyl groups per molecule is 200 or lower. Mw/F is preferably 150 or lower and more preferably 100 or lower. By using a (meth)acrylate monomer in which Mw/F is low, the oxygen transmission rate of the wavelength conversion layer which is formed by curing the quantum dot-containing polymerizable composition can be reduced, and thus the light fastness of the wavelength conversion member can be improved. In addition, by using a (meth)acrylate monomer in which Mw/F is low, the crosslinking density of the polymer in the wavelength conversion layer can be increased, and the fracture of the wavelength conversion layer can be prevented, which is preferable.

Specific examples of the (meth)acrylate monomer in which Mw/F is 200 or lower include pentaerythritol triacrylate, pentaerythritol tetraacrylate, trimethylolpropane trimethacrylate, dipentaerythritol hexaacrylate, and tricyclodecane dimethanol diacrylate.

The amount of the polyfunctional (meth)acrylate monomer used with respect to 100 parts by mass of the total amount of the polymerizable compound in the quantum dot-containing polymerizable composition is preferably 5 parts by mass or more from the viewpoint of the strength of the coating film and is preferably 95 parts by mass or less from the viewpoint of suppressing the gelation of the composition.

In addition, the amount of the radically polymerizable compound used with respect to 100 parts by mass of the total amount of the quantum dot-containing polymerizable composition is preferably 10 to 99.9 parts by mass, more preferably 50 to 99.9 parts by mass, and still more preferably 92 to 99 parts by mass.

(Polymerization Initiator)

Optionally, the quantum dot-containing polymerizable composition may include a polymerization initiator. As the polymerization initiator, a polymerization initiator which is preferable depending on the kind of the polymerizable compound in the quantum dot-containing polymerizable composition is preferably used. In a case where the polymerizable compound is radically polymerizable, the quantum dot-containing polymerizable composition may include a well-known radical initiator. The details of the polymerization initiator can be found in paragraph “0037” of JP2013-043382A. The content of the polymerization initiator is preferably 0.1 mol % or higher and more preferably 0.5 mol % to 2 mol % with respect to the total mass of the polymerizable compound included in the quantum dot-containing polymerizable composition.

(Solvent)

Optionally, the quantum dot-containing polymerizable composition may include a solvent. In this case, the kind and addition amount of the solvent used are not particularly limited. For example, as the solvent, one organic solvent or a mixture of two or more organic solvents may be used.

<Barrier Film (Substrate)>

The barrier films 10 and 20 are films having a function of suppressing permeation of water and/or oxygen. In the embodiment, the barrier layers 12 and 22 are provided on the supports 11 and 21, respectively. In this configuration, due to the presence of the supports, the strength of the wavelength conversion member 1D is improved, and the films can be easily manufactured.

In the wavelength conversion members according to the embodiment, in the barrier films 10 and 20 in which the barrier layers 12 and 22 are supported by the supports 11 and 21 are provided such that the barrier layers 12 and 22 are adjacent to opposite main surfaces of the wavelength conversion layer 30. However, the barrier layers 12 and 22 are not necessarily supported by the supports 11 and 21. In addition, in a case where the supports 11 and 21 have sufficient barrier properties, the barrier layers may include only the supports 11 and 21.

In addition, it is preferable that the wavelength conversion member includes the two barrier films 10 and 20 as in the embodiment. However, the wavelength conversion member may include one barrier film.

The total light transmittance of the barrier film in the visible range is 80% or higher and more preferably 90% or higher. The visible range refers to a wavelength range of 380 nm to 780 nm, and the total light transmittance refers to an average light transmittance value in the visible range.

The oxygen transmission rate of the barrier films 10 and 20 is preferably 1.00 cm³/(m²·day·atm) or lower. Here, the oxygen transmission rate is a value measured using an oxygen transmission rate measuring device (OX-TRAN 2/20 (trade name), manufactured by Mocon Inc.) under conditions of measurement temperature: 23° C. and relative humidity: 90%. The oxygen transmission rate of the barrier film 10 and 20 is more preferably 0.10 cm³/(m²·day·atm) or lower, still more preferably 0.01 cm³/(m²·day·atm) or lower, and still more preferably 0.001 cm³/(m²·day·atm) or lower.

The barrier films 10 and 20 have not only a gas barrier function of blocking oxygen and a function of blocking water (water vapor). In the wavelength conversion member 1D, the moisture permeability (water vapor transmission rate) of the barrier film 10 and 20 is 0.10 g/(m²·day·atm) or lower. The moisture permeability of the barrier film 10 and 20 is preferably 0.01 g/(m²·day·atm) or lower.

(Support)

In the wavelength conversion member 1D, at least one main surface of the wavelength conversion layer 30 is supported by the support 11 or 21. Here, “main surface” refers to a surface (a front surface or a rear surface) of the wavelength conversion layer which is disposed on a visible side or a backlight side when the wavelength conversion member is used. The same can also be applied to main surfaces of other layers and members.

As in the embodiment, it is preferable that front and rear main surfaces of the wavelength conversion layer 30 are supported by the supports 11 and 21.

From the viewpoints of impact resistance and the like of the wavelength conversion member, the average thickness of the supports 11 and 21 is preferably 10 μm to 500 μm, more preferably 20 μm to 400 μm, and still more preferably 30 μm to 300 μm. In a configuration where the retroreflection of light is increased as in a case where the concentration of the quantum dots 30A and 30B in the wavelength conversion layer 30 is reduced or a case where the thickness of the wavelength conversion layer 30 is reduced, it is preferable that the absorbance of light at a wavelength of 450 nm is low. Therefore, from the viewpoint of suppressing a decrease in brightness, the average thickness of the supports 11 and 21 is preferably 40 μm or less and more preferably 25 μm or less.

In order to further reduce the concentration of the quantum dots 30A and 30B in the wavelength conversion layer 30 or to further reduce the thickness of the wavelength conversion layer 30, it is necessary that the number of times where the excitation light passes through the wavelength conversion layer is increased by providing means for increasing retroreflection of light, for example, a plurality of prism sheets in the retroreflecting member 2B of the backlight unit to maintain a display color of a LCD. Accordingly, it is preferable that the support is a transparent support which is transparent to visible light. Here, “transparent to visible light” represents that the light transmittance in the visible range is 80% or higher and preferably 85% or higher. The light transmittance used as an index for transparency can be measured using a method described in JIS-K 7105. That is, using an integrating sphere light transmittance measuring device, the total light transmittance and the scattered light amount are measured, and the diffuse transmittance is subtracted from the total light transmittance to obtain the light transmittance. The details of the support can be found in paragraphs “0046” to “0052” of JP2007-290369A and paragraphs “0040” to “0055” of JP2005-096108A.

In addition, the in-plane retardation Re(589) of the supports 11 and 21 at a wavelength of 589 nm is preferably 1000 nm or lower, more preferably 500 nm or lower, and still more preferably 200 nm or lower.

When whether or not foreign matter or defects are present is inspected after the preparation of the wavelength conversion member 1D, foreign matter or defects can be easily found by disposing two polarizing plates at extinction positions and inserting the wavelength conversion member between the two polarizing plates to observe the wavelength conversion member. In a case where Re(589) of the support is in the above-described range, foreign matter or defects can be easily found during the inspection using the polarizing plates, which is preferable.

Here, Re(589) is measured using KOBRA 21ADH or WR (manufactured by Oji Scientific Instruments Co., Ltd.) by causing light at a wavelength of 589 nm to be incident in a film normal direction. The measurement wavelength λ nm can be selected by manually changing a wavelength selective filter or changing a measured value using a program or the like.

As the supports 11 and 21, a support having barrier properties against oxygen and water is preferable. Preferable examples of the support include a polyethylene terephthalate film, a film which includes a polymer having a cyclic olefin structure, and a polystyrene film.

(Barrier Layer)

It is preferable that the support 11 or 21 includes the barrier layer 12 or 22 including at least one inorganic barrier layer 12b or 22b which is formed adjacent to a surface on the wavelength conversion layer 30 side.

As shown in FIGS. 2A and 2B, the barrier layer 12 or 22 may include at least one organic barrier layer 12a or 22a which is formed between the support 11 or 21 and the inorganic barrier layer 12b or 22b. The organic barrier layer 12a or 22a may be provided between the inorganic barrier layer 12b or 22b and the wavelength conversion layer 30. From the viewpoint of improving weather fastness, it is preferable that a plurality of barrier layers are provided because barrier properties can be further improved. It is also preferable that the organic barrier layer is provided between the inorganic barrier layer 12b or 22b and the wavelength conversion layer 30. In this case, the organic barrier layer may also be referred to as a barrier coating layer (overcoat layer).

The barrier layer 12 or 22 is formed on a surface of the support 11 or 21. Accordingly, the barrier film 10 or 20 includes: the support 11 or 21; and the barrier layer 12 or 22 that is formed on the support 11 or 21. In a case where the barrier layer 12 or 22 is provided, it is preferable that the support has high heat resistance. In the wavelength conversion member 1D, a layer of the barrier film 10 or 20 which is adjacent to the wavelength conversion layer 30 may be an inorganic barrier layer or an organic barrier layer and is not particularly limited.

From the viewpoint of improving weather fastness, it is preferable that the barrier layer 12 or 22 includes a plurality of layers because barrier properties can be further improved. However, as the number of layers increases, the light transmittance of the wavelength conversion member is likely to decrease. Therefore, it is preferable that the barrier layer 12 or 22 is designed in consideration of excellent light transmittance and barrier properties.

[Inorganic Barrier Layer] “Inorganic layer” is a layer including an inorganic material as a major component and is preferably a layer consisting only of an inorganic material.

The inorganic barrier layer 12b or 22b which is preferable for the barrier layer 12 or 22 is not particularly limited, and various inorganic compounds such as a metal, an inorganic oxide, an inorganic nitride, or an inorganic oxynitride can be used. As an element constituting the inorganic material, silicon, aluminum, magnesium, titanium, tin, indium, or cerium is preferable. The inorganic material may include one element or two or more elements among the above elements. Specific examples of the inorganic compound include silicon oxide, silicon oxynitride, aluminum oxide, magnesium oxide, titanium oxide, tin oxide, an indium oxide alloy, silicon nitride, aluminum nitride, and titanium nitride. In addition, as the inorganic barrier layer, a metal film such as an aluminum film, a silver film, a tin film, a chromium film, a nickel film, or a titanium film may be provided.

In particular, an inorganic barrier layer including a silicon oxide, a silicon nitride, a silicon oxynitride, a silicon carbide, or an aluminum oxide is preferable. The inorganic barrier layer formed of the above materials has excellent adhesiveness with the organic barrier layer. Therefore, in a case where a pin hole is formed on the inorganic barrier layer, the organic barrier layer can be effectively embedded in the pin hole, and barrier properties can be further suppressed.

In addition, it is more preferable that the inorganic barrier layer is formed of a silicon nitride from the viewpoint of suppressing light absorption in the barrier layer.

A method of forming the inorganic barrier layer is not particularly limited. For example, various film forming methods in which a film forming material can be evaporated or scattered to be deposited on a deposition target surface can be used.

Examples of the method of forming the inorganic barrier layer include: a vacuum deposition method of heating and depositing an inorganic material such as an inorganic oxide, an inorganic nitride, an inorganic oxynitride, or a metal; an oxidation deposition method of introducing oxygen gas and oxidizing an inorganic material as a raw material for deposition; a sputtering method of introducing argon gas and oxygen gas and sputtering an inorganic material as a target material for deposition; a physical vapor deposition (PVD) method, such as an ion plating method, of heating an inorganic material with a plasma beam generated by a plasma gun for deposition; and in a case where a deposited film formed of silicon oxide is formed, a chemical vapor deposition method of using an organic silicon compound as a raw material.

The thickness of the inorganic barrier layer may be 1 nm to 500 nm and is preferably 5 nm to 300 nm and more preferably 10 nm to 150 nm. By adjusting the thickness of the adjacent inorganic layer to be in the above-described range, light absorption in the inorganic barrier layer can be suppressed while realizing excellent barrier properties, and the wavelength conversion member having a high light transmittance can be provided.

[Organic Barrier Layer] “Organic layer” is a layer including an organic material as a major component in which the content of the organic material is preferably 50 mass % or higher, more preferably 80 mass % or higher, and still more preferably 90 mass % or higher. The details of the organic barrier layer can be found in paragraphs “0020” to “0042” of JP2007-290369A and paragraphs “0074” to “0105” of JP2005-096108A. It is preferable that the organic barrier layer includes a cardo polymer. As a result, adhesiveness between the organic barrier layer and an adjacent layer, in particular, adhesiveness between the organic barrier layer and the inorganic barrier layer is improved, and more favorable barrier properties can be realized. The details of the cardo polymer can be found in paragraphs “0085” to “0095” of JP2005-096108A. The thickness of the organic barrier layer is preferably in a range of 0.05 μm to 10 μm and more preferably in a range of 0.5 to 10 μm. In a case where the organic barrier layer is formed using a wet coating method, the thickness of the organic barrier layer is preferably in a range of 0.5 to 10 μm and more preferably in a range of 1 μm to 5 μm. In a case where the organic layer is formed using a dry coating method, the thickness of the organic layer is preferably in a range of 0.05 μm to 5 μm and more preferably in a range of 0.05 μm to 1 μm. By adjusting the thickness of the organic barrier layer, which is formed using a wet coating method or a dry coating method, adhesiveness with the inorganic layer can be further improved.

Other details of the inorganic barrier layer and the organic barrier layer can be found in JP2007-290369A, JP2005-096108A, and US2012/0113672A1.

(Design Change of Barrier Film)

In the wavelength conversion member 1D, the wavelength conversion layer, the inorganic barrier layer, the organic barrier layer, and the support may be laminated in this order. The support may be provided between the inorganic barrier layer and the organic barrier layer, between two organic barrier layers, or between two inorganic barrier layers.

(Unevenness Imparting Layer (Mat Layer))

It is preferable that the barrier film 10 or 20 includes an unevenness imparting layer (mat layer) which imparts an uneven structure to a surface of the barrier film 10 opposite to the wavelength conversion layer 30 side. In a case where the barrier film includes the mat layer, blocking properties and slipping properties of the barrier film can be improved, which is preferable. It is preferable that the mat layer is layer including particles. Examples of the particles include inorganic particles such as silica, alumina, a metal oxide and organic particles such as crosslinked polymer particles. In addition, it is preferable that the mat layer is provided on a surface of the barrier film opposite to the wavelength conversion layer. However, the mat layer may be provided on both surfaces of the barrier film.

(Adhesive Layer)

The wavelength conversion member 1D which is manufactured using a second manufacturing method described below includes the adhesive layer 50. The adhesive layer 50 is not particularly limited, and examples thereof include a layer obtained by curing an adhesive. Various adhesives which are used for manufacturing a polarizing plate in the related art can be used as long as they are curable. From the viewpoints of weather fastness, polarizability, and the like, an adhesive which is curable by active energy rays such as ultraviolet light is preferable. Among the adhesives which are curable by active energy rays, an active energy ray-curable adhesive which includes, as one active energy ray-curable component, an epoxy compound, more specifically, an epoxy compound not having an aromatic ring in the molecule as described in JP2004-245925A is preferable. In addition, with the active energy ray-curable adhesive, not only a cationically polymerizable compound such as an epoxy compound as a representative example but also typically a polymerization initiator, in particular, a photocationic polymerization initiator for generating a cationic species or Lewis acid to initiate polymerization of the cationically polymerizable compound when irradiated with active energy rays are mixed. Further, various additives such as a thermal cationic polymerization initiator which initiates polymerization when heated or a photosensitizer may be mixed with the active energy ray-curable adhesive.

(Light Scattering Layer)

The wavelength conversion member 1D may have a light scattering function for efficiently extracting the fluorescence of the quantum dots to the outside. The light scattering function may be provided in the wavelength conversion layer 30, or a layer having a light scattering function may be separately provided as a light scattering layer.

On the other hand, in the wavelength conversion member 1D according to the embodiment, the gettering agent 40 functions as a scatterer in the wavelength conversion layer 30. Therefore, in a case where it is necessary to improve the light scattering function in the wavelength conversion layer 30, scattering particles may be newly added.

In addition, the light scattering layer may be provided on a surface of the support opposite to the wavelength conversion layer. In a case where the mat layer is provided, it is preferable that the mat layer functions not only as an unevenness imparting layer but also as a light scattering layer.

[Method of Manufacturing Wavelength Conversion Member]

### <First Manufacturing Method>

Hereinafter, an example of a method of manufacturing the wavelength conversion member 1D in which the substrates 10 and 20 (hereinafter, the barrier films 10 and 20) are provided on both surfaces of the wavelength conversion layer 30 will be described, the substrates 10 and 20 including the barrier layers 12 and 22 on the supports 11 and 21.

In the embodiment, the wavelength conversion layer 30 can be formed by applying the prepared quantum dot-containing polymerizable composition to surfaces of the barrier films 10 and 20 and irradiating the quantum dot-containing polymerizable composition with light or heating the quantum dot-containing polymerizable composition to be cured. Examples of a coating method include various coating methods such as a curtain coating method, a dip coating method, a spin coating method, a printing coating method, a spray coating method, a slot coating method, a roll coating method, a slide coating method, a blade coating method, a gravure coating method, or a wire bar method.

Curing conditions can be appropriately set depending on the kind of the polymerizable compound used and the composition of the polymerizable composition. In addition, in a case where the quantum dot-containing polymerizable composition includes a solvent, a drying treatment is performed to remove the solvent before curing.

In the first manufacturing method, the quantum dot-containing polymerizable composition may be cured in a state where the quantum dot-containing polymerizable composition is interposed between the two supports.

As described above, the wavelength conversion member 1D according to the embodiment may adopt any one of the configuration of the first embodiment (FIG. 2A) and the third embodiment (FIG. 3A) in which the gettering agent 40 is evenly dispersed and the configuration of the second embodiment (FIG. 2B) and the fourth embodiment (FIG. 3B) where the getting agent 40 is unevenly dispersed in the layer boundary region of the wavelength conversion layer 30 (also referred to as “unevenly dispersed in the outer surface”). The first embodiment is different from the second embodiment, in the preparation of the quantum dot-containing polymerizable composition and the step of forming the wavelength conversion layer 30.

In the wavelength conversion member according to the first embodiment, the gettering agent 40 is evenly dispersed in the wavelength conversion layer 30, and the coating film can be easily formed with a typical coating method by using the quantum dot-containing polymerizable composition to which the gettering agent 40 is added (dispersed) as a coating solution. During the manufacturing of the wavelength conversion member according to the first embodiment, when various materials included in the quantum dot-containing polymerizable composition are mixed with each other to prepare a coating solution, it is preferable that the gettering agent 40 is added in the form of a gettering agent dispersion in order to prevent aggregation of the gettering agent.

In the wavelength conversion member according to the second embodiment, the gettering agent 40 is unevenly dispersed in the layer boundary region of the wavelength conversion layer 30 (also referred to as “unevenly dispersed in the outer surface”). A method of forming the wavelength conversion layer having the above-described configuration is not particularly limited, and examples thereof include: a method of simultaneously forming layers of a multi-layer film with a die co-casting coater using the quantum dot-containing polymerizable composition to which the gettering agent 40 is added and the quantum dot-containing polymerizable composition to which the gettering agent 40 is not added; and a method of sequentially forming layers of a multi-layer film by multi-stage coating. In any method, the solution used can be selected such that a cured layer of the quantum dot-containing polymerizable composition to which the gettering agent is added is disposed on the outermost surface of the wavelength conversion layer and such that a cured layer of the quantum dot-containing polymerizable composition to which the gettering agent is not added is disposed on the inside surface of the wavelength conversion layer.

As the coating solutions used for manufacturing the wavelength conversion member according to the second embodiment, it is necessary to prepare a coating solution to which the gettering agent 40 is added and a coating solution to which the gettering agent 40 is not added.

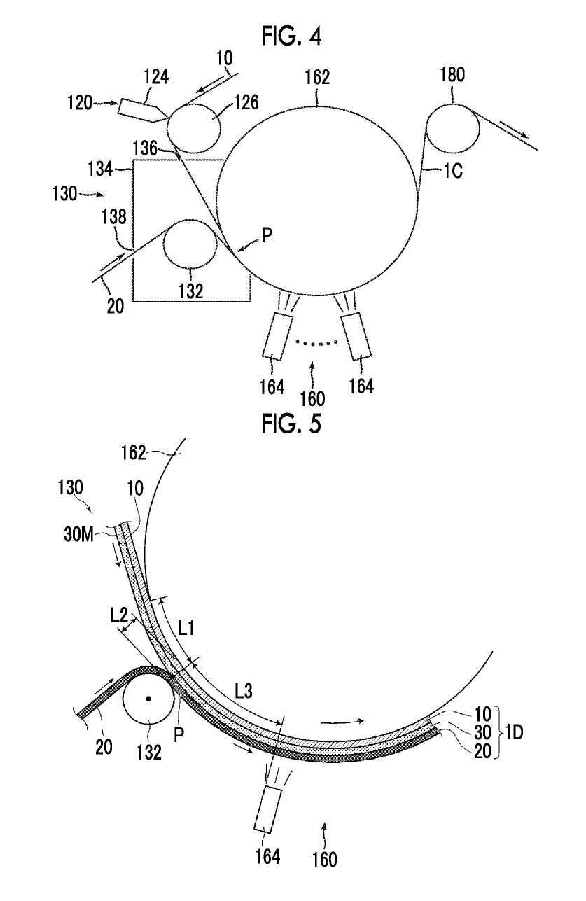

The method of manufacturing the wavelength conversion member 1D according to the first embodiment using the first manufacturing method will be described below with reference to FIGS. 4 and 5. However, the present invention is not limited to the following configuration.

FIG. 4 is a diagram showing a schematic configuration of an example of a device of manufacturing the wavelength conversion member 1D. FIG. 5 is an enlarged view showing a part of the manufacturing device shown in FIG. 4. Steps of manufacturing the wavelength conversion member using the manufacturing device shown in FIGS. 4 and 5 include at least: a step of forming a coating film by applying the quantum dot-containing polymerizable composition to a surface of the first barrier film 10 (hereinafter, referred to as “first film”) which is continuously transported; a step of interposing the coating film between the first film and the second film by laminating the second barrier film 20 (hereinafter, referred to as “second film”), which is continuously transported, on the coating film; and a step of forming the wavelength conversion layer (cured layer) by winding any one of the first film and the second film around a backup roller in a state where the coating film is interposed between the first film and the second film, and irradiating the coating film with light to be cured and polymerized while being continuously transported. In the embodiment, as the first film and the second film, the barrier films having barrier properties against oxygen and water are used. With the above-described configuration, the wavelength conversion member 1D in which opposite surfaces of the wavelength conversion layer are protected by the barrier films can be obtained. A single layer of the wavelength conversion member may be protected by the barrier film. In this case, it is preferable that the barrier film side is a side close to the external air.

More specifically, first, the first film 10 is continuously transported from a transporter (not shown) to a coating portion 120. The first film 10 is transported from the transporter at a transport speed of, for example, 1 to 50 m/min. In this case, the transport speed is not limited to the above value. During the transportation, for example, a tension of 20 to 150 N/m and preferably 30 to 100 N/m is applied to the first film 10.

In the coating portion 120, the quantum dot-containing polymerizable composition (hereinafter, also referred to as “coating solution”) is applied to a surface of the first film 10, which is continuously transported, to form a coating film 30M (refer to FIG. 5) thereon. In the coating portion 120, for example, a die coater 124 and a backup roller 126 which is disposed to face the die coater 124 are provided. A surface of the first film 10 opposite to the surface on which the coating film 30M is formed is wound around the backup roller 126, and the coating solution is applied from a jetting port of the die coater 124 to the surface of the first substrate 10 which is continuously transported, to form the coating film 30M thereon. Here, the coating film 30M refers to the quantum dot-containing polymerizable composition which is applied to the first film 10 and is not cured.

In the embodiment, the die coater 124 to which an extrusion coating method is applied is used as a coating device, but the present invention is not limited thereto. For example, coating devices to which various methods such as a curtain coating method, an extrusion coating method, a rod coating method, or a roll coating method are applied can be used.

The first film 10 which has passed through the coating portion 120 and on which the coating film 30M is formed is continuously transported to a laminating portion 130. In the laminating portion 130, the second film 20 which is continuously transported is laminated on the coating film 30M such that the coating film 30M is interposed between the first film 10 and the second film 20.

In the laminating portion 130, a laminating roller 132 and a heating chamber 134 which surrounds the laminating roller 132 are provided. In the heating chamber 134, an opening 136 through which the first film 10 passes and an opening 138 through which the second film 20 passes are provided.

At a position opposite to the laminating roller 132, a backup roller 162 is disposed. The first film 10 on which the coating film 30M is formed is continuously transported to a laminating position P in a state where a surface opposite to the surface on which the coating film 30M is formed is wound around the backup roller 162. The laminating position P refers to a position where contact between the second film 20 and the coating film 30m starts. It is preferable that the first film 10 is wound around the backup roller 162 before reaching the laminating position P. The reason for this is that, even in a case where wrinkles are formed in the first film 10, the wrinkles are corrected and removed by the backup roller 162 before reaching the laminating position P. Therefore, it is preferably that a distance L1 from a position (contact position) where the first film 10 is wound around the backup roller 162 to the laminating position P is long. For example, the distance L1 is preferably 30 mm or longer, and the upper limit value thereof is typically determined based on a diameter and a pass line of the backup roller 162.

In the embodiment, the second film 20 is laminated by the backup roller 162 which is used in a curing portion 160 and the laminating roller 132. That is, the backup roller 162 which is used in the curing portion 160 also functions as a roller used in the laminating portion 130. However, the present invention is not limited to this configuration. A laminating roller other than the backup roller 162 may be provided in the laminating portion 130 such that the backup roller 162 does not function as a roller used in the laminating portion 130.

By using the backup roller 162, which is used in the curing portion 160, in the laminating portion 130, the number of rollers can be reduced. In addition, the backup roller 162 can also be used as a heat roller for heating the first film 10.

The second film 20 transported from a transporter (not shown) is wound around the laminating roller 132 and is continuously transported between the laminating roller 132 and the backup roller 162. At the laminating position P, the second film 20 is laminated on the coating film 30M formed on the first film 10. As a result, the coating film 30M is interposed between the first film 10 and the second film 20. Laminating described herein represents that the second film 20 is laminated on the coating film 30M.

It is preferable that a distance L2 between the laminating roller 132 and the backup roller 162 is more than the total thickness of the first film 10, the wavelength conversion layer (cured layer) 30 obtained by curing and polymerizing the coating film 30M, and the second film 20. In addition, it is preferable that L2 is equal to or less than a length obtained by adding 5 mm to the total thickness of the first film 10, the coating film 30M, and the second film 20. By adjusting the distance L2 to be equal to or less than the length obtained by adding 5 mm to the total thickness, permeation of bubbles into a gap between the second film 20 and the coating film 30M can be prevented. Here, the distance L2 between the laminating roller 132 and the backup roller 162 refers to the shortest distance between the outer circumferential surface of the laminating roller 132 and the outer circumferential surface of the backup roller 162.

Regarding the rotational accuracy of the laminating roller 132 and the backup roller 162, the radial run-out is 0.05 or less and preferably 0.01 or less. As the radial run-out decreases, the thickness distribution of the coating film 30M can be reduced.

In addition, in order to suppress thermal deformation after the coating film 30M is interposed between the first film 10 and the second film 20, a difference between the temperature of the backup roller 162 and the temperature of the first film 10 in the curing portion 160 and a difference between the temperature of the backup roller 162 and the temperature of the second film 20 are preferably 30° C. or lower, more preferably 15° C. or lower, and still more preferably 0° C.

In a case where the heating chamber 134 is provided in order to reduce the differences from the temperature of the backup roller 162, it is preferable that the first film 10 and the second film 20 are heated in the heating chamber 134. For example, hot air is supplied from a hot air blower (not shown) into the heating chamber 134 such that the first film 10 and the second film 20 can be heated.

The first film 10 may be wound around the backup roller 162 whose temperature is controlled such that the first film 10 is heated by the backup roller 162.

On the other hand, regarding the second film 20, by using a heat roller as the laminating roller 132, the second film 20 can be heated by the laminating roller 132. In this case, the heating chamber 134 and the heat roller are not essential and can be optionally provided.

Next, the coating film 30M is continuously transported to the curing portion 160 while interposed between the first film 10 and the second film 20. In the configuration shown in the drawing, curing in the curing portion 160 is performed by light irradiation. However, in a case where the polymerizable compound included in the quantum dot-containing polymerizable composition is polymerizable by heating, curing can be performed by heating such as blowing of warm air.

At a position opposite to the backup roller 162, a light irradiating device 164 is provided. The first film 10 and the second film 20 between which the coating film 30M is interposed are continuously transported between the backup roller 162 and the light irradiating device 164. Light irradiated by the light irradiating device may be determined depending on the kind of the polymerizable compound in the quantum dot-containing polymerizable composition. For example, ultraviolet light is used. Here, the ultraviolet light refers to light in a wavelength range of 280 to 400 nm. As a light source which emits ultraviolet light, for example, a low-pressure mercury lamp, a middle-pressure mercury lamp, a high-pressure mercury lamp, a ultrahigh-pressure mercury lamp, a carbon arc lamp, a metal halide lamp, or a xenon lamp can be used. The irradiation dose may be determined in a range where the polymerization and curing reaction can be performed. For example, the coating film 30M is irradiated with ultraviolet light in an irradiation dose of 100 to 10000 mJ/cm².

In the curing portion 160, the first film 10 is wound around the backup roller 162 in a state where the coating film 30M is interposed between the first film 10 and the second film 20, and the coating film 30M is irradiated with light by the light irradiating device 164 while being continuously transported. As a result, the coating film 30M is cured to form the wavelength conversion layer (cured layer) 30.

In the embodiment, the first film 10 side is wound around the backup roller 162 and is continuously transported. However, the second film 20 may be wound around the backup roller 162 and may be continuously transported.

“Being around the backup roller 162” represents a state where any one of the first film 10 and the second film 20 is in contact with a surface of the backup roller 162 at a given lap angle. Accordingly, the first film 10 and the second film 20 move in synchronization with the rotation of the backup roller 162 while being continuously transported. Any one of the first film 10 and the second 20 only has to be wound around the backup roller 162 while at least being irradiated with ultraviolet light.

The backup roller 162 includes a main body having a cylindrical shape and a rotating shaft that is disposed at opposite end portions of the main body. The main body of the backup roller 162 has a diameter φ of, for example, 200 to 1000 mm. The diameter φ of the backup roller 162 is not particularly limited. The diameter φ is preferably 300 to 500 mm from the viewpoints of curling deformation of the laminated film, facility costs, and rotational accuracy. By mounting a temperature controller on the main body of the backup roller 162, the temperature of the backup roller 162 can be controlled.

The temperature of the backup roller 162 can be determined in consideration of heat generation during the light irradiation, the curing efficiency of the coating film 30M, and the wrinkling of the first film 10 and the second film 20 on the backup roller 162. The temperature of the backup roller 162 is set to be in a temperature range of preferably 10° C. to 95° C. and more preferably 15° C. to 85° C. Here, the temperature regarding a roller refers to the surface temperature of the roller.

A distance L3 between the laminating position P and the light irradiating device 164 can be made to be, for example, 30 mm or more.

The coating film 30M is irradiated with light to form the cured layer 30, and the wavelength conversion member 1D including the first film 10, the cured layer 30, and the second film 20 is manufactured. The wavelength conversion member 1D is peeled off from the backup roller 162 by a peeling roller 180. The wavelength conversion member 1D is continuously transported to a winder (not shown) and then is wound in a roll shape by the winder.

A method of manufacturing the wavelength conversion member 1D according to the second embodiment is the same as the method of manufacturing the wavelength conversion member 1D according to the first embodiment, except for the method of forming the coating film 30M of the wavelength conversion layer. In the second embodiment, as described above, the coating film 30M is formed by applying the coating solution to which the gettering agent is added, and the coating solution to which the gettering agent is not added by co-casting or in different steps.

In the case of co-casting, in the coating portion 120, a die co-casting coater is used as the die coater 124, and the coating solutions are applied from a jetting port of the die co-casting coater 124 to a surface of the first film 10 which is continuously transported. As a result, the coating film 30M as a multi-layer cast film including the coating film to which the gettering agent is added and the coating film to which the gettering agent is not added is formed.

<Second Manufacturing Method>

In the first manufacturing method of the wavelength conversion member, the second film is laminated before curing the coating film 30M after forming the coating film 30M on the first film, and then the coating film 30M is cured in a state where the coating film 30M is interposed between the first film and the second film. On the other hand, in the second manufacturing method, the coating film 30M is formed on the first film and is optionally dried and cured to form the wavelength conversion layer (cured layer). Optionally, a coating layer is formed on the wavelength conversion layer, and then the second film is laminated on the wavelength conversion layer with an adhesive (and the coating layer) interposed therebetween to form the wavelength conversion member 1D. The coating layer includes one or more other layers such as an inorganic layer and can be formed using a well-known method.

Hereinabove, the two configurations of the manufacturing steps of the wavelength conversion member 1D have been described. However, the present invention is not limited to the above-described configurations.

[Backlight Unit]

As described above, the backlight unit 2 shown in FIG. 1 includes: a surface light source 1C including a light source 1A, which emits primary light (blue light L_{B}), and a light guide plate 1B which guides and emits the primary light emitted from the light source 1A; a wavelength conversion member 1D that is provided on the surface light source 1C; a retroreflecting member 2B that is disposed to face the surface light source 1C with the wavelength conversion member 1D interposed therebetween; and a reflection plate 2A that is disposed to face the wavelength conversion member 1D with the surface light source 1C interposed therebetween. The wavelength conversion member 1D are excited by excitation light, which is at least a portion of the excitation light L_{B} emitted from the surface light source 1C, to emit fluorescence and emits secondary light (L_{G}, L_{R}) which includes the fluorescence and the primary light L_{B} which does not function as excitation light.

From the viewpoint of realizing high brightness and high color reproducibility, it is preferable that the backlight unit includes a multi-wavelength light source. For example, it is preferable that blue light having a center emission wavelength in a wavelength range of 430 to 480 nm and having a full width at half maximum of emission peak of 100 nm or less, green light having a center emission wavelength in a wavelength range of 500 to 600 nm and having a full width at half maximum of emission peak of 100 nm or less, and red light having a center emission wavelength in a wavelength range of 600 to 680 nm and having a full width at half maximum of emission intensity peak of 100 nm or less are emitted.

From the viewpoint of further improving brightness and color reproducibility, the wavelength range of the blue light emitted from the backlight unit 2 is preferably 430 to 480 nm and more preferably 440 to 460 nm.

From the same viewpoint, the wavelength range of the green light emitted from the backlight unit 2 is preferably 520 to 560 nm and more preferably 520 to 545 nm.

In addition, from the same viewpoint, the wavelength range of the red light emitted from the backlight unit is preferably 600 to 680 nm and more preferably 610 to 640 nm.

In addition, from the same point, the full width at half maximum of the emission intensity of each of the blue light, the green light, and the red light emitted from the backlight unit is preferably 80 nm or less, more preferably 50 nm or less, still more preferably 40 nm or less, and still more preferably 30 nm or less. In particular, it is more preferable that the full width at half maximum of the emission intensity of the blue light is 25 nm or less.

The backlight unit 2 includes at least the wavelength conversion member 1D and the surface light source 1C. As the light source 1A, for example, a light source which emits blue light having a center emission wavelength in a wavelength range of 430 nm to 480 nm, or a light source which emits ultraviolet light can be used. As the light source 1A, for example, a light emitting diode or a laser light source can be used.

As shown in FIG. 1, the surface light source 1C may include: the light source 1A; and the light guide plate 1B that guides and emits the primary light emitted from the light source 1A. Alternatively, the surface light source 1C may include: the light source 1A that is disposed along with a plane parallel to the wavelength conversion member 1D; and a diffusion plate that is provided instead of the light guide plate 1B. The former surface light source is called an edge light mode, and the latter surface light source is called a direct backlight mode.

In the embodiment, the example in which the surface light source is used as the light source has been described. As the light source, a light surface other than the surface light source can also be used.

(Configuration of Backlight Unit)

In the above description regarding FIG. 1, the configuration of the backlight unit is an edge light mode including a light guide plate or a reflection plate as a component. However, the configuration of the backlight unit may be a direct backlight mode. As the light guide plate, a well-known light guide plate can be used without any particular limitation.

In addition, as the reflection plate 2A, a well-known reflection plate can be used without any particular limitation. The details of the reflection plate 2A can be found in JP3416302B, JP3363565B, JP4091978B, and JP3448626B, the contents of which are incorporated herein by reference.

The retroreflecting member 2B may be formed of a well-known diffusion plate, a diffusion sheet, a prism sheet (for example, BEF series, manufactured by Sumitomo 3M Ltd.), or a light guide. The configuration of the retroreflecting member 2B can be found in JP3416302B, JP3363565B, JP4091978B, and JP3448626B, the contents of which are incorporated herein by reference.

[Liquid Crystal Display Device]

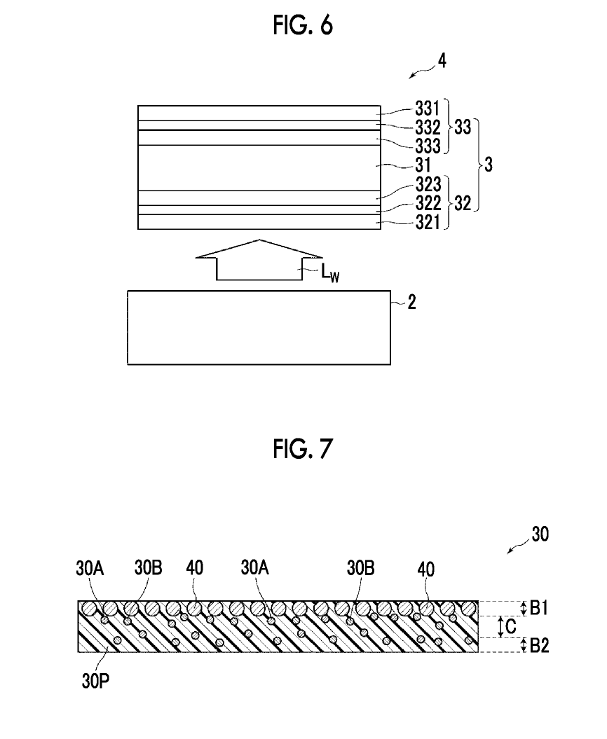

The above-described backlight unit 2 can be applied to a liquid crystal display device. As shown in FIG. 6, a liquid crystal display device 4 includes: the backlight unit 2 according to the embodiment; and a liquid crystal cell unit 3 that is disposed to face the retroreflecting member side of the backlight unit 2.

In the liquid crystal cell unit 3, as shown in FIG. 6, a liquid crystal cell 31 is interposed between polarizing plates 32 and 33. In the polarizing plates 32 and 33, opposite main surfaces of polarizers 322 and 332 are protected by polarizing plate protective films 321 and 323 and polarizing plate protective films 331 and 333, respectively.

Regarding each of the liquid crystal cell 31, the polarizing plates 32 and 33, and other components which constitute the liquid crystal display device 4, a product prepared using a well-known method or a commercially available product can be used without any particular limitation. In addition, of course, a well-known interlayer such as an adhesive layer can be provided between respective layers.

As a driving mode of the liquid crystal cell 31, various modes such as a twisted nematic (TN) mode, a super twisted nematic (STN) mode, a vertical alignment (VA) mode, an in-plane switching (IPS) mode, or an optically compensated bend (OCB) mode can be used without any particular limitation. The liquid crystal cell is preferably a VA mode, an OCB mode, an IPS mode, or a TN mode but is not limited thereto. Examples of the configuration of the VA mode liquid crystal display device include a configuration shown in FIG. 2 described in JP2008-262161A. However, a specific configuration of the liquid crystal display device is not particularly limited, and a well-known configuration can be adopted.

Optionally, the liquid crystal display device 4 further includes an optical compensation member for optical compensation or a sub-functional layer such as an adhesive layer. Further, in addition to (or instead of) a color filter substrate, a thin film transistor substrate, a lens film, a diffusion sheet, a hard coat layer, an anti-reflection layer, a low-reflection layer, or an anti-glare layer, a surface layer such as a forward scattering layer, a primer layer, an antistatic layer, or a undercoat layer may be disposed.

The backlight-side polarizing plate 32 may include a phase difference film as the polarizing plate protective film 323 on the liquid crystal cell 31 side. As this phase difference film, for example, a well-known cellulose acylate film can be used.

The backlight unit 2 and the liquid crystal display device 4 includes the wavelength conversion member according to the present invention having a small light loss. Therefore, the backlight unit 2 and the liquid crystal display device 4 exhibit the same effects as those of the wavelength conversion member according to the present invention, in which peeling at an interface of the wavelength conversion layer including quantum dots is not likely to occur, the emission intensity is not likely to decrease, and the brightness is high.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples.

1. Preparation of First Barrier Film (Including No Coating Layer)

As a support, a polyethylene terephthalate film (PET film; trade name: COSMOSHINE A4300, manufactured by Toyobo Co., Ltd.) having a thickness of 50 μm was used, and a first organic layer and an inorganic layer were formed in this order on a single surface of the support in the following procedure.

Trimethylolpropane triacrylate (TMPTA, manufactured by Daicel-Cytec Co., Ltd.) and a photopolymerization initiator (ESACURE KTO 46, manufactured by Lamberti S.p.A.) were prepared and were weighed such that a mass ratio thereof was 95:5. These components were dissolved in methyl ethyl ketone. As a result, a coating solution having a solid content concentration of 15% was obtained. This coating solution was applied to the above-described PET film using a roll-to-roll method with a die coater and was allowed to pass through a drying zone at 50° C. for 3 minutes. Next, in a nitrogen atmosphere, the coating solution was irradiated with ultraviolet light (cumulative irradiation dose: about 600 mJ/cm²) to be cured, and the PET film was wound. The thickness of the first organic layer formed on the support (the PET film) was 1 μm.

Next, using a roll-to-roll CVD apparatus, an inorganic barrier layer (silicon nitride layer) was formed on a surface of the first organic layer. As raw material gases, silane gas (flow rate: 160 sccm), ammonia gas (flow rate: 370 sccm), hydrogen gas (flow rate: 590 sccm), and nitrogen gas (flow rate: 240 sccm) were used. As a power supply, a high-frequency power supply having a frequency of 13.56 MHz was used. The film forming pressure was 40 Pa, and the achieved thickness was 50 nm. In this way, a first barrier film 1 in which the first organic layer and the inorganic barrier layer were formed in this order on the support was prepared. The moisture permeability of the barrier film measured under conditions of 40° C. and 90% RH was 0.001 g/(m²·day·atm).

A first barrier film 2 (used in Example 23) was prepared using the same method as the method of forming the first barrier film 1, except that the achieved thickness was changed to 15 nm. The moisture permeability of the barrier film measured under conditions of 40° C. and 90% RH was 0.01 g/(m²·day·atm).

A first barrier film 3 (used in Example 24) was prepared using the same method as the method of forming the first barrier film 1, except that the achieved thickness was changed to 5 nm. The moisture permeability of the barrier film measured under conditions of 40° C. and 90% RH was 0.1 g/(m²·day·atm).

2. Preparation of Second Barrier Film (Including Coating Layer)

A second organic layer (barrier coating layer) was formed on a surface of the inorganic layer of the first barrier film 1 in the following procedure.

A urethane acrylic polymer (ACRYD 8BR 500, manufactured by Taisei Fine Chemical Co., Ltd.) and a photopolymerization initiator (IRAGACURE 184, manufactured by Ciba Specialty Chemicals Inc.) were weighed such that a mass ratio thereof was 95:5, and these components were dissolved in methyl ethyl ketone. As a result, a coating solution having solid content concentration of 15% was prepared. This coating solution was directly applied to a surface of the inorganic layer in the first barrier film 1 using a roll-to-roll method with a die coater and was allowed to pass through a drying zone at 100° C. for 3 minutes. Next, while holding the first barrier film 1 with a heat roll heated to 60° C., the coating solution was irradiated with ultraviolet light (cumulative irradiation dose: about 600 mJ/cm²) to be cured, and the first barrier film 1 was wound. The thickness of the coating layer formed on the support was 1 μm. In this way, a second barrier film in which the second organic layer (barrier coating layer) was provided as the barrier coating layer was prepared.

3. Preparation of Quantum Dot-Containing Polymerizable Composition

A quantum dot-containing polymerizable composition 1 was prepared at the following mixing ratio.

In the following description, the content of quantum dots 1 and 2 in a toluene dispersion including the quantum dots 1 or 2 was 1 mass %. In the quantum dots 1 and 2 used, a core was CdSe and a shell was ZnS.

A quantum dot-containing polymerizable composition 2 having the same composition as the quantum dot-containing polymerizable composition 1 was prepared, except that a monomer 2 (methyl methacrylate (MMA): manufactured by Mitsubishi Gas Chemical Company Inc.) was used instead of the monomer 1.

Next, a quantum dot-containing polymerizable composition 3 having the same composition as the quantum dot-containing polymerizable composition 1 was prepared, except that a monomer 3 (trimethylolpropane triacrylate (TMPTA): manufactured by Daicel-Cytec Co., Ltd.) was used instead of the monomer 1.

In addition, quantum dot-containing polymerizable compositions 4 and 5 were prepared at the following mixing ratio.

Quantum Dot-Containing Polymerizable Composition 1

| | | |
|---|---|---|
| Toluene Dispersion Including Quantum Dots 1 | 10 | Parts By Mass |
| (Maximum Emission Wavelength: 520 nm) | | |
| Toluene Dispersion Including Quantum Dots 2 | 1 | Part By Mass |
| (Maximum Emission Wavelength: 630 nm) | | |
| Monomer 1 (Lauryl Methacrylate: Manufactured | 99 | Parts By Mass |
| By Osaka Organic Chemical Industry Ltd.) | | |
| Photopolymerization Initiator (IRGACURE 819 | 1 | Part By Mass |
| (Manufactured By BASF SE) | | |

Quantum Dot-Containing Polymerizable Composition 4

| | | |
|---|---|---|
| Toluene Dispersion Including Quantum Dots 3 | 10 | Parts By Mass |
| (Maximum Emission Wavelength: 530 nm) | | |
| Toluene Dispersion Including Quantum Dots 4 | 1 | Part By Mass |
| (Maximum Emission Wavelength: 620 nm) | | |
| Monomer 1 (Lauryl Methacrylate: Manufactured | 99 | Parts By Mass |
| By Osaka Organic Chemical Industry Ltd.) | | |
| Photopolymerization Initiator (IRGACURE 819 | 1 | Part By Mass |
| (Manufactured By BASF SE) | | |

Quantum Dot-Containing Polymerizable Composition 5

| | | |
|---|---|---|
| Toluene Dispersion Including Quantum Dots 3 | 20 | Parts By Mass |
| (Maximum Emission Wavelength: 530 nm) | | |
| Toluene Dispersion Including Quantum Dots 4 | 2 | Parts By Mass |
| (Maximum Emission Wavelength: 620 nm) | | |
| Monomer 4 (Isobornyl Methacrylate: | 85 | Parts By Mass |
| Manufactured By Kyoeisha Chemical Co., Ltd.) | | |
| Monomer 5 (1,9-Nonanediol Diacrylate: | 15 | Parts By Mass |
| Manufactured By Kyoeisha Chemical Co., Ltd.) | | |
| Photopolymerization Initiator (IRGACURE 819 | 1 | Part By Mass |
| (Manufactured By BASF SE) | | |

As a toluene solution including quantum dots 3, INP530-25 (manufactured by NN-LABS LLC.) as a green quantum dot dispersion having an emission wavelength of 530 nm was used. As a toluene solution including quantum dots 4, INP620-25 (manufactured by NN-LABS LLC.) as a green quantum dot dispersion having an emission wavelength of 620 nm was used. Here, INP530-25 and INP620-25 (manufactured by NN-LABS LLC.) were quantum dots in which a core was InP, a shell was ZnS, and a ligand was oleylamine. INP530-25 and INP620-25 were dispersed in toluene in a concentration of 3 mass %.

Table 1 shows the layer configuration, the composition of the quantum dot-containing composition in the wavelength conversion layer (the kind of the matrix and the composition of the gettering agent), the moisture permeability of the barrier film, and the evaluation results regarding each of Examples 1 to 30 of the present invention and Comparative Examples 1 to 20.

In the item “Layer Configuration”, Greek number I represents a configuration the wavelength conversion member including the adhesive layer was manufactured using the second manufacturing method, and Greek number III represents a configuration the member including no adhesive layer was manufactured using the first manufacturing method.

I: adhesive layer provided (second manufacturing method)

III: no adhesive layer provided (first manufacturing method)

In addition, in the item “Layer Configuration”, Arabic numbers 1 to 6 shows the barrier films used and whether or not the coating layer was provided in the wavelength conversion layer. The details are as follows.

1: first barrier film/wavelength conversion layer/first barrier film

2: first barrier film/wavelength conversion layer/second barrier film

3: first barrier film/wavelength conversion layer/coating layer/first barrier film

4: first barrier film/wavelength conversion layer/coating layer/second barrier film

5: second barrier film/wavelength conversion layer/coating layer (adhesive layer)/second barrier film

6: second barrier film/wavelength conversion layer/second barrier film

In the item “Layer Configuration”, the item “Gettering Agent Distribution” shows a configuration in which the gettering agent is dispersed in the wavelength conversion layer. “Dispersed” shows the first embodiment (FIG. 2A) and the third embodiment (FIG. 3A), and “Unevenly Dispersed in Outer Surface” shows the second embodiment (FIG. 2B) and the fourth embodiment (FIG. 3B).

The gettering agent was added to the quantum dot-containing polymerizable compositions 1 to 5 in the respective addition amounts so as to obtain the compositions shown in Table 1 to 3. As a result, the quantum dot-containing polymerizable compositions used in the respective examples were prepared. After the preparation, each of the quantum dot-containing polymerizable compositions was filtered through a filter formed of polypropylene having a pore size of 0.2 μm and was dried under a reduced pressure for 30 minutes was prepare a coating solution.

In Table 1, “mass %” represent 1 mass % with respect to the total mass of the quantum dot-containing polymerizable composition to which the gettering agent was added. The same shall be applied to the following “mass %”.

As zeolite used in Examples 33 to 38, Examples 41 to 43, and Examples 46 to 48, a high silica zeolite HSZ-722HOA (manufactured by Tosoh Corporation) was used. The average particle size of zeolite used was 6 μm.

4. Method of Manufacturing Wavelength Conversion Layer

(First Manufacturing Method: III in Table 1, First Embodiment)

The first barrier film used in each example was prepared, and the quantum dot-containing polymerizable composition according to each example was applied to the surface of the inorganic barrier layer using a die coater while being continuously transported at 1 m/min with a tension of 60 N/m. As a result, a coating film having a thickness of 50 μm was formed. Next, the first barrier film in which the coating film was formed was wound around the backup roller, and the barrier film according to each example was laminated on the coating film such that the barrier layer faced the coating film. Next, the laminate was wound around the backup roller in a state where the coating film was interposed between the barrier films, and was irradiated with ultraviolet light while being continuously transported. As a result, the wavelength conversion layer according to the first embodiment was obtained. The wavelength conversion layer was cut into three regions in the thickness direction, and ratios between occupied area ratios of the gettering agent in the respective regions are shown in Table 1. Regarding the occupied area ratios, a cross-section of the wavelength conversion layer in the thickness direction was observed with a transmission electron microscope (JEM-2100, manufactured by JEOL Ltd.) to measure occupied area ratios S_{B1}, S_{B2}, and S_{C} of the gettering agent particles in the measurement areas. In each region, the TEM spot size was 1 nm, and the measurement magnification was 30000 times. Three visual fields each of which had an area of about 4 μm×3 μm were used.

(First Manufacturing Method: III in Table 1, Second Embodiment)

A wavelength conversion layer according to the second embodiment was used using the same method as in the first manufacturing method, except that a multi-layer coating film having a thickness of 50 μm was formed by simultaneously applying the quantum dot-containing polymerizable composition to which the gettering agent was added the quantum dot-containing polymerizable composition to which the gettering agent was not added using a die co-casting coater such that a layer including the gettering agent was positioned on the outermost surface. The wavelength conversion layer was cut into three regions in the thickness direction, and ratios between occupied area ratios of the gettering agent in the respective regions are shown in Table 1.

The diameter of the backup roller was 300 mm, and the temperature of the backup roller was 50° C. The irradiation dose of ultraviolet light was 2000 mJ/cm². In addition, L1 was 50 mm, L2 was 1 mm, and L3 was 50 mm

The coating film was cured by ultraviolet irradiation to form a cured layer (wavelength conversion layer). As a result, a wavelength conversion member according to each example was manufactured. In the wavelength conversion member, the thickness of the cured layer in each example was 50±2 μm. The thickness accuracy of the cured layer was excellent at ±4%. In addition, wrinkling was not observed on the obtained wavelength conversion member.

(Second Manufacturing Method: I in Table 1)

Using the same method as the first manufacturing method, the quantum dot-containing polymerizable composition used in each example was applied to the surface of the inorganic barrier layer of the first barrier film using a die coater. As a result, a coating film having a thickness of 50 μm was formed. Next, the first barrier film in which the coating film was formed was wound around the backup roller, and the coating film was irradiated with ultraviolet light in the same irradiation dose as in the first manufacturing method to be cured. As a result, a cured layer (wavelength conversion layer) was formed.

Next, the barrier film according to each example in which the adhesive was applied to the barrier layer surface was laminated such that the adhesive surface was in contact with the cured layer. Next, the laminate was wound around the backup roller in a state where the coating film was interposed between the barrier films, and the adhesive was cured. As a result, a wavelength conversion member according to each example was manufactured. In the wavelength conversion member, the thickness of the cured layer according to each example and the thickness accuracy thereof were the same as those in the first manufacturing method. Wrinkling was not observed in the obtained wavelength conversion member.

(Evaluation of Brightness Deterioration Resistance)

A commercially available tablet terminal (Kindle Fire HDX 7″, manufactured by Amazon.com Inc.) was disassembled to extract a backlight unit. The wavelength conversion member according to each example which was cut into a rectangular shape was placed on a light guide plate of the extracted backlight unit, and two prism sheets whose surface roughness pattern directions were perpendicular to each other were laminated thereon. The brightness of light, which was emitted from a blue light source and passed through the wavelength conversion member and the two prism sheets was measured using a brightness meter (SR3, manufactured by Topcon Corporation) provided at a distance of 740 mm perpendicular to the surface of the light guide plate. The measurement was performed at inner positions which were at a distant of 5 mm from four corners of the wavelength conversion member, and the average value (Y0) of the measured values at the four corners was set as an evaluation value.

In a room held at 25° C. and 60% RH, the wavelength conversion member according to each example was placed on a commercially available blue light source (OPSM-H150X142B, manufactured by OPTEX FA Co., Ltd.), and was continuously irradiated with blue light for 100 hours.

After the continuous irradiation, the brightness (Y1) at the four corners of the wavelength conversion member was measured using the same method as that of the evaluation of the brightness before the continuous irradiation. A change rate (ΔY) between the brightness before the continuous irradiation and the brightness after the continuous irradiation was obtained and was set as an index for a brightness change. The results are shown in Table 1.

ΔY=(Y0−Y1)÷Y0×100

Evaluation Criteria

ΔY<20: Excellent

20≦ΔY≦30: Good

30<ΔY: No Good

(Evaluation of Peelability)

Using the same method as that in the evaluation of the brightness deterioration resistance, the wavelength conversion member according to each example was continuously irradiated with blue light. After the continuous irradiation, the 180° peeling adhesive strength of the wavelength conversion member according to each example was measured using a method described in JIS Z 0237. The peelability of each example was evaluated from the measurement results based on the following evaluation criteria. The obtained results are shown in Table 1.

The 180° peeling adhesive strength was 2.015 N/10 mm or higher: Excellent

The 180° peeling adhesive strength was 0.5 N/10 mm or higher and lower than 2.015

N/10 mm: Good

The 180° peeling adhesive strength was lower than 0.2 N/10 mm: No Good

As shown in Tables 1 to 3, the effectiveness of the present invention was shown.

TABLE 1

| | | | QD Layer | | | | | | | |
|---|---|---|---|---|---|---|---|---|---|---|
| | Layer Configuration | | Quantum Dot- | | | | Addition | Barrier | | |
| | Prepara- | Gettering | Containing | | | | Amount of | Layer | Evaluation Results | |
| | tion | Agent | Polymerizable | Gettering | | | Gettering | Moisture | Brightness | |
| | Method | Distribution | Composition No. | Agent | S_{B1}/S_{C} | S_{B2}/S_{C} | Agent | Permeability | Deterioration | Peelability |
| Example 1 | I-1 | Dispersed | Composition 1 | Magnesium | 1.0 | 1.1 | 1 wt % | 0.001 | Excellent | Excellent |
| | | | | Oxide | | | | | | |
| Example 2 | I-2 | Dispersed | Composition 1 | Magnesium | 1.2 | 1.1 | 1 wt % | 0.001 | Excellent | Excellent |
| | | | | Oxide | | | | | | |
| Example 3 | I-3 | Dispersed | Composition 1 | Magnesium | 0.9 | 1.1 | 1 wt % | 0.001 | Excellent | Excellent |
| | | | | Oxide | | | | | | |
| Example 4 | I-4 | Dispersed | Composition 1 | Magnesium | 1.0 | 1.2 | 1 wt % | 0.001 | Excellent | Excellent |
| | | | | Oxide | | | | | | |
| Example 5 | III-1 | Dispersed | Composition 1 | Magnesium | 0.9 | 1.0 | 1 wt % | 0.001 | Excellent | Excellent |
| | | | | Oxide | | | | | | |
| Example 6 | III-2 | Dispersed | Composition 1 | Magnesium | 1.0 | 0.8 | 1 wt % | 0.001 | Excellent | Excellent |
| | | | | Oxide | | | | | | |
| Example 7 | I-1 | Unevenly | Composition 1 | Magnesium | 3.2 | 1.1 | 1 wt % | 0.001 | Excellent | Excellent |
| | | Dispersed in | | Oxide | | | | | | |
| | | Outer Surface | | | | | | | | |
| Example 8 | I-2 | Unevenly | Composition 1 | Magnesium | 2.5 | 0.8 | 1 wt % | 0.001 | Excellent | Excellent |
| | | Dispersed in | | Oxide | | | | | | |
| | | Outer Surface | | | | | | | | |
| Example 9 | I-3 | Unevenly | Composition 1 | Magnesium | 4.1 | 1.2 | 1 wt % | 0.001 | Excellent | Excellent |
| | | Dispersed in | | Oxide | | | | | | |
| | | Outer Surface | | | | | | | | |
| Example 10 | I-4 | Unevenly | Composition 1 | Magnesium | 5.1 | 1.2 | 1 wt % | 0.001 | Excellent | Excellent |
| | | Dispersed in | | Oxide | | | | | | |
| | | Outer Surface | | | | | | | | |
| Example 11 | III-1 | Unevenly | Composition 1 | Magnesium | 2.5 | | 1 wt % | 0.001 | Excellent | Excellent |
| | | Dispersed in | | Oxide | | | | | | |
| | | Outer Surface | | | | | | | | |
| Example 12 | III-2 | Unevenly | Composition 1 | Magnesium | 4.2 | 1.1 | 1 wt % | 0.001 | Excellent | Excellent |
| | | Dispersed in | | Oxide | | | | | | |
| | | Outer Surface | | | | | | | | |
| Example 13 | III-1 | Dispersed | Composition 1 | Magnesium | 1.0 | 1.1 | 0.2 wt % | 0.001 | Good | Good |
| | | | | Oxide | | | | | | |
| Example 14 | III-1 | Dispersed | Composition 1 | Magnesium | 0.8 | 1.2 | 5 wt % | 0.001 | Excellent | Excellent |
| | | | | Oxide | | | | | | |
| Example 15 | III-1 | Dispersed | Composition 1 | Barium | 1.2 | 1.2 | 1 wt % | 0.001 | Excellent | Excellent |
| | | | | Oxide | | | | | | |
| Example 16 | III-1 | Dispersed | Composition 1 | Sodium | 1.1 | 0.9 | 1 wt % | 0.001 | Excellent | Excellent |
| | | | | Sulfate | | | | | | |
| Example 17 | III-1 | Dispersed | Composition 1 | Calcium | 1.0 | 1.1 | 1 wt % | 0.001 | Excellent | Excellent |
| | | | | Chloride | | | | | | |
| Example 18 | III-1 | Dispersed | Composition 1 | Calcium | 0.9 | 0.8 | 1 wt % | 0.001 | Excellent | Excellent |
| | | | | Oxide | | | | | | |
| Example 19 | III-1 | Dispersed | Composition 1 | Aluminum | 1.0 | 1.1 | 1 wt % | 0.001 | Excellent | Excellent |
| | | | | Oxide | | | | | | |
| Example 20 | III-1 | Dispersed | Composition 1 | Aluminum | 1.0 | 0.9 | 1 wt % | 0.001 | Excellent | Excellent |
| | | | | Oxide | | | | | | |
| | | | | Octylate | | | | | | |
| Example 21 | III-1 | Dispersed | Composition 2 | Magnesium | 0.9 | 1.2 | 1 wt % | 0.001 | Excellent | Excellent |
| | | | | Oxide | | | | | | |
| Example 22 | III-1 | Dispersed | Composition 3 | Magnesium | 1.2 | 1.2 | 1 wt % | 0.001 | Excellent | Excellent |
| | | | | Oxide | | | | | | |
| Example 23 | III-1 | Dispersed | Composition 1 | Magnesium | 1.0 | 1.0 | 1 wt % | 0.01 | Excellent | Excellent |
| | | | | Oxide | | | | | | |
| Example 24 | III-1 | Dispersed | Composition 1 | Magnesium | 1.1 | 0.8 | 1 wt % | 0.1 | Good | Excellent |
| | | | | Oxide | | | | | | |
| Example 25 | III-1 | Unevenly | Composition 1 | Barium | 3.5 | 0.9 | 1 wt % | 0.001 | Excellent | Excellent |
| | | Dispersed in | | Oxide | | | | | | |
| | | Outer Surface | | | | | | | | |
| Example 26 | III-1 | Unevenly | Composition 1 | Sodium | 5.0 | 1.0 | 1 wt % | 0.001 | Excellent | Excellent |
| | | Dispersed in | | Sulfate | | | | | | |
| | | Outer Surface | | | | | | | | |
| Example 27 | III-2 | Dispersed | Composition 1 | Barium | 1.0 | 0.9 | 1 wt % | 0.001 | Excellent | Excellent |
| | | | | Oxide | | | | | | |
| Example 28 | III-2 | Dispersed | Composition 1 | Sodium | 1.0 | 1.1 | 1 wt % | 0.001 | Excellent | Excellent |
| | | | | Sulfate | | | | | | |
| Example 29 | III-2 | Unevenly | Composition 1 | Barium | 4.6 | 0.8 | 1 wt % | 0.001 | Excellent | Excellent |
| | | Dispersed in | | Oxide | | | | | | |
| | | Outer Surface | | | | | | | | |
| Example 30 | III-2 | Unevenly | Composition 1 | Sodium | 3.9 | 1.0 | 1 wt % | 0.001 | Excellent | Excellent |
| | | Dispersed in | | Sulfate | | | | | | |
| | | Outer Surface | | | | | | | | |
| Comparative | I-1 | Unevenly | Composition 1 | — | — | — | — | 0.001 | No Good | No Good |
| Example 1 | | Dispersed in | | | | | | | | |
| | | Outer Surface | | | | | | | | |
| Comparative | I-2 | Unevenly | Composition 1 | — | — | — | — | 0.001 | No Good | No Good |
| Example 2 | | Dispersed in | | | | | | | | |
| | | Outer Surface | | | | | | | | |
| Comparative | I-3 | Unevenly | Composition 1 | — | — | — | — | 0.001 | No Good | No Good |
| Example 3 | | Dispersed in | | | | | | | | |
| | | Outer Surface | | | | | | | | |
| Comparative | I-4 | Unevenly | Composition 1 | — | — | — | — | 0.001 | No Good | No Good |
| Example 4 | | Dispersed in | | | | | | | | |
| | | Outer Surface | | | | | | | | |
| Comparative | III-1 | Unevenly | Composition 1 | — | — | — | — | 0.001 | No Good | No Good |
| Example 5 | | Dispersed in | | | | | | | | |
| | | Outer Surface | | | | | | | | |
| Comparative | III-2 | Unevenly | Composition 1 | — | — | — | — | 0.001 | No Good | No Good |
| Example 6 | | Dispersed in | | | | | | | | |
| | | Outer Surface | | | | | | | | |
| Comparative | III-1 | Unevenly | Composition 2 | — | — | — | — | 0.001 | No Good | No Good |
| Example 7 | | Dispersed in | | | | | | | | |
| | | Outer Surface | | | | | | | | |
| Comparative | III-1 | Unevenly | Composition 3 | — | — | — | — | 0.001 | No Good | No Good |
| Example 8 | | Dispersed in | | | | | | | | |
| | | Outer Surface | | | | | | | | |
| Comparative | I-1 | Dispersed | Composition 1 | Magnesium | 1.0 | 1.1 | 1 wt % | 1.0 | No Good | No Good |
| Example 9 | | | | Oxide | | | | | | |
| Comparative | I-1 | Unevenly | Composition 1 | Magnesium | 2.9 | 1.1 | 1 wt % | 1.0 | No Good | No Good |
| Example 10 | | Dispersed in | | Oxide | | | | | | |
| | | Outer Surface | | | | | | | | |
| Comparative | III-1 | Dispersed | Composition 1 | Magnesium | 1.0 | 0.8 | 1 wt % | 1.0 | No Good | No Good |
| Example 11 | | | | Oxide | | | | | | |
| Comparative | III-1 | Dispersed | Composition 1 | Barium | 1.2 | 0.9 | 1 wt % | 1.0 | No Good | Good |
| Example 12 | | | | Oxide | | | | | | |
| Comparative | III-1 | Dispersed | Composition 1 | Sodium | 1.1 | 1.1 | 1 wt % | 1.0 | No Good | Good |
| Example 13 | | | | Sulfate | | | | | | |
| Comparative | III-1 | Dispersed | Composition 2 | Magnesium | 1.2 | 1.1 | 1 wt % | 1.0 | No Good | Good |
| Example 14 | | | | Oxide | | | | | | |
| Comparative | III-1 | Dispersed | Composition 3 | Magnesium | 1.0 | 1.2 | 1 wt % | 1.0 | No Good | Good |
| Example 15 | | | | Oxide | | | | | | |
| Comparative | III-1 | Unevenly | Composition 1 | Magnesium | 3.7 | 0.9 | 1 wt % | 1.0 | No Good | Good |
| Example 16 | | Dispersed in | | Oxide | | | | | | |
| | | Outer Surface | | | | | | | | |
| Comparative | III-1 | Dispersed | Composition 1 | Magnesium | 1.0 | 1.1 | 5 wt % | 1.0 | No Good | Good |
| Example 17 | | | | Oxide | | | | | | |
| Comparative | III-1 | Unevenly | Composition 1 | Magnesium | 5.5 | 1.0 | 1 wt % | 1.0 | No Good | Good |
| Example 18 | | Dispersed in | | Oxide | | | | | | |
| | | Outer Surface | | | | | | | | |
| Comparative | III-2 | Dispersed | Composition 1 | Magnesium | 1.0 | 1.2 | 1 wt % | 1.0 | No Good | Good |
| Example 19 | | | | Oxide | | | | | | |
| Comparative | III-2 | Unevenly | Composition 1 | Magnesium | 4.3 | 0.9 | 1 wt % | 1.0 | No Good | Good |
| Example 20 | | Dispersed in | | Oxide | | | | | | |
| | | Outer Surface | | | | | | | | |

TABLE 2

| | | | QD Layer | | | | | | | |
|---|---|---|---|---|---|---|---|---|---|---|
| | Layer Configuration | | Quantum | | | | Addition | Barrier | | |
| | | Gettering | Dot-Containing | | | | Amount of | Layer | Evaluation Results | |
| | Preparation | Agent | Polymerizable | Gettering | | | Gettering | Moisture | Brightness | |
| | Method | Distribution | Composition No. | Agent | S_{B1}/S_{C} | S_{B2}/S_{C} | Agent | Permeability | Deterioration | Peelability |
| Example 31 | I-5 | Dispersed | Composition 1 | Magnesium | 0.9 | 0.8 | 1 wt % | 0.001 | Excellent | Excellent |
| | | | | Oxide | | | | | | |
| Example 32 | III-6 | Dispersed | Composition 1 | Magnesium | 1.0 | 1.1 | 1 wt % | 0.001 | Excellent | Excellent |
| | | | | Oxide | | | | | | |
| Example 33 | III-1 | Dispersed | Composition 1 | Zeolite | 1.0 | 1.1 | 1 wt % | 0.001 | Excellent | Excellent |
| Example 34 | III-2 | Dispersed | Composition 1 | Zeolite | 0.9 | 0.8 | 1 wt % | 0.001 | Excellent | Excellent |
| Example 35 | III-6 | Dispersed | Composition 1 | Zeolite | 1.0 | 1.1 | 1 wt % | 0.001 | Excellent | Excellent |
| Example 36 | I-3 | Dispersed | Composition 1 | Zeolite | 1.0 | 1.0 | 1 wt % | 0.001 | Excellent | Excellent |
| Example 37 | I-4 | Dispersed | Composition 1 | Zeolite | 1.1 | 0.8 | 1 wt % | 0.001 | Excellent | Excellent |
| Example 38 | I-5 | Dispersed | Composition 1 | Zeolite | 1.2 | 1.2 | 1 wt % | 0.001 | Excellent | Excellent |

TABLE 3

| | | | QD Layer | | | | | | | |
|---|---|---|---|---|---|---|---|---|---|---|
| | Layer Configuration | | Quantum | | | | Addition | Barrier | | |
| | | Gettering | Dot-Containing | | | | Amount of | Layer | Evaluation Results | |
| | Preparation | Agent | Polymerizable | Gettering | | | Gettering | Moisture | Brightness | |
| | Method | Distribution | Composition No. | Agent | S_{B1}/S_{C} | S_{B2}/S_{C} | Agent | Permeability | Deterioration | Peelability |
| Example 39 | I-5 | Dispersed | Composition 4 | Magnesium | 1.0 | 0.9 | 1 wt % | 0.001 | Excellent | Excellent |
| | | | | Oxide | | | | | | |
| Example 40 | III-6 | Dispersed | Composition 4 | Magnesium | 1.2 | 1.2 | 1 wt % | 0.001 | Excellent | Excellent |
| | | | | Oxide | | | | | | |
| Example 41 | III-6 | Dispersed | Composition 4 | Zeolite | 1.0 | 1.1 | 1 wt % | 0.001 | Excellent | Excellent |
| Example 42 | III-6 | Dispersed | Composition 4 | Zeolite | 1.0 | 1.0 | 1 wt % | 0.001 | Excellent | Excellent |
| Example 43 | III-6 | Dispersed | Composition 4 | Zeolite | 1.0 | 1.0 | 0.2 wt % | 0.001 | Good | Good |
| Example 44 | I-5 | Dispersed | Composition 5 | Magnesium | 1.1 | 0.9 | 1 wt % | 0.001 | Excellent | Excellent |
| | | | | Oxide | | | | | | |
| Example 45 | III-6 | Dispersed | Composition 5 | Magnesium | 1.0 | 1.1 | 1 wt % | 0.001 | Excellent | Excellent |
| | | | | Oxide | | | | | | |
| Example 46 | III-6 | Dispersed | Composition 5 | Zeolite | 1.2 | 1.2 | 1 wt % | 0.001 | Excellent | Excellent |
| Example 47 | III-6 | Dispersed | Composition 5 | Zeolite | 1.1 | 0.8 | 1 wt % | 0.001 | Excellent | Excellent |
| Example 48 | III-6 | Dispersed | Composition 5 | Zeolite | 1.1 | 0.8 | 0.2 wt % | 0.001 | Excellent | Excellent |

What is claimed is:

1. A wavelength conversion member comprising:
a wavelength conversion layer including at least one kind of quantum dots and a gettering agent, the quantum dots being excited by excitation light to emit fluorescence, and the gettering agent trapping at least one of water or oxygen; and
a barrier layer having a moisture permeability of 0.1 g/(m²·day·atm) or lower that is formed on at least one surface of the wavelength conversion layer,
wherein the wavelength conversion layer is a layer obtained by curing a polymerizable composition including the quantum dots and the gettering agent.

2. The wavelength conversion member according to claim 1,
wherein the gettering agent is evenly dispersed in the wavelength conversion layer.

3. The wavelength conversion member according to claim 1,
wherein the gettering agent is unevenly dispersed in a layer boundary region of the wavelength conversion layer.

4. The wavelength conversion member according to claim 1,
wherein the gettering agent is a compound or a composition on which water and oxygen are adsorbed.

5. The wavelength conversion member according to claim 1,
wherein the gettering agent includes at least one compound selected from the group consisting of a metal oxide, a metal halide, a metal sulfate, a metal perchlorate, a metal carbonate, a metal alkoxide, a metal carboxylate, a metal chelate, and an aluminosilicate.

6. The wavelength conversion member according to claim 1,
wherein at least one adhesive layer is provided between the wavelength conversion layer and the barrier layer.

7. The wavelength conversion member according to claim 1,
wherein the barrier layer includes a silicon oxide, a silicon nitride, a silicon carbide, or an aluminum oxide.

8. The wavelength conversion member according to claim 1,
wherein a light diffusion layer is provided on a surface of the barrier layer opposite to a surface on the wavelength conversion layer side.

9. The wavelength conversion member according to claim 1,
wherein the barrier layer is provided on both surfaces of the wavelength conversion layer.

10. A backlight unit comprising:
a light source that emits primary light;
the wavelength conversion member according to claim 1 that is provided on the light source;
a retroreflecting member that is disposed to face the light source with the wavelength conversion member interposed therebetween; and
a reflection plate that is disposed to face the wavelength conversion member with the light source interposed therebetween,
wherein the wavelength conversion member is excited by excitation light, which is at least a portion of the primary light emitted from the light source, to emit the fluorescence and emits at least light which includes secondary light including the fluorescence.

11. A liquid crystal display device comprising:
the backlight unit according to claim 10; and
a liquid crystal cell unit that is disposed to face the retroreflecting member side of the backlight unit.
